(19) United States
(12) Patent Application Publication
(10) Pub. No.: US 2025/0228004 A1
(43) Pub. Date: Jul. 10, 2025

(54) THIN FILM TRANSISTOR SUBSTRATE, MANUFACTURING METHOD THEREOF AND DISPLAY APPARATUS COMPRISING THE SAME

(71) Applicant: LG Display Co., Ltd., Seoul (KR)

(72) Inventors: Sunggu KIM, Paju-si (KR); Sohyung LEE, Paju-si (KR); KwangHeum LEE, Paju-si (KR); Chaewoon LEE, Paju-si (KR)

(21) Appl. No.: 18/736,288

(22) Filed: Jun. 6, 2024

(30) Foreign Application Priority Data
Jan. 5, 2024 (KR) 10-2024-0001857

(51) Int. Cl. H01L 27/12; H10K 59/121

(52) U.S. Cl. CPC H10D 86/60; H10D 86/0221; H10D 86/423; H10K 59/1213

(57) ABSTRACT

The present disclosure relates to thin film transistor substrate, manufacturing method thereof and display apparatus comprising the same. The thin film transistor substrate includes a first thin film transistor and a second thin film transistor on a base substrate, the first thin film transistor includes a first active layer on the base substrate, and a first gate electrode spaced apart from the first active layer and overlapping at least part of the first active layer, and the second thin film transistor includes a second active layer on the base substrate and a second gate electrode spaced apart from the second active layer and overlapping at least part of the second active layer, the first active layer includes a first oxide semiconductor layer and a second oxide semiconductor layer on the first oxide semiconductor layer, the second active layer includes a first oxide semiconductor layer and a second oxide semiconductor layer on the first oxide semiconductor layer, a third oxide semiconductor layer on the second oxide semiconductor layer.

### CROSS-REFERENCE TO RELATED APPLICATIONS

This application claims the benefit of priority of the Korean Patent Application No. 10-2024-0001857 filed on Jan. 5, 2024, which is hereby incorporated by reference as if fully set forth herein.

### BACKGROUND

### Technical Field

The present disclosure relates to a thin film transistor substrate, a manufacturing method thereof, and a display apparatus, and to a thin film transistor including an oxide semiconductor layer having a crystalline structure, a manufacturing method thereof, and a display apparatus including such a thin film transistor.

### Description of the Related Art

Since thin film transistors can be manufactured on glass or plastic substrates, they are widely used as switching or driving elements of display apparatuses such as liquid crystal display apparatuses or organic light-emitting devices.

Based on the material constituting the active layer, thin film transistors can be divided into amorphous silicon thin film transistors in which amorphous silicon is used as an active layer, polycrystalline silicon thin film transistors in which polycrystalline silicon is used as an active layer, and oxide semiconductor thin film transistors in which oxide semiconductors are used as active layers.

An oxide semiconductor thin film transistor (Oxide Semiconductor TFT) having a large resistance change according to the oxygen content has the advantage of being able to easily obtain desired physical properties. In addition, the manufacturing cost is low because the oxide constituting the active layer may be formed at a relatively low temperature in the manufacturing process of the oxide semiconductor thin film transistor. Due to the nature of the oxide, since the oxide semiconductor is transparent, it is also advantageous to implement a transparent display. However, the oxide semiconductor thin film transistor has a disadvantage of having low mobility.

To improve reliability and mobility by preventing physical and chemical damage or defects that cause deterioration of oxide semiconductor thin film transistors, there is a method of making oxide semiconductors into crystalline structures.

Recently, a gate-in-panel (GIP) structure in which the gate driver is embedded in the display panel in the form of a thin film transistor has been applied to a display apparatus. In order to improve the performance of the display apparatus, a large number of thin film transistors are disposed in the gate driver.

### BRIEF SUMMARY

An embodiment of the present disclosure provides a thin film transistor substrate to which a multilayer structure of an active layer is selectively applied.

Another embodiment of the present disclosure provides a thin film transistor substrate having an active layer including an oxide semiconductor layer having a crystalline structure that improves mobility and reliability.

Another embodiment of the present disclosure provides a method of manufacturing a thin film transistor substrate that improves mobility and reliability.

Another embodiment of the present disclosure is to provide a display apparatus including a thin film transistor substrate that improves mobility and

Another embodiment of the present disclosure is to provide a thin film transistor to which a multilayer structure of an active layer is applied.

In addition to the technical features of the present disclosure as mentioned above, additional technical characteristics and features of the present disclosure will be clearly understood by those skilled in the art from the following description of the present disclosure.

In accordance with an aspect of the present disclosure, a thin film transistor substrate includes a first thin film transistor and a second thin film transistor on a base substrate, wherein the first thin film transistor includes a first active layer on the base substrate, and a first gate electrode spaced apart from the first active layer and overlapping at least part of the first active layer, and the second thin film transistor includes a second active layer on the base substrate and a second gate electrode spaced apart from the second active layer and overlapping at least part of the second active layer, the first active layer includes a first oxide semiconductor layer and a second oxide semiconductor layer on the first oxide semiconductor layer, the second active layer includes a first oxide semiconductor layer and a second oxide semiconductor layer on the first oxide semiconductor layer, a third oxide semiconductor layer on the second oxide semiconductor layer, the first oxide semiconductor layer of the first active layer has an amorphous structure, the second oxide semiconductor layer of the first active layer has a crystalline structure, the first oxide semiconductor layer and the third oxide semiconductor layer of the second active layer have an amorphous structure, and the second oxide semiconductor layer of the second active layer has an crystalline structure.

The first oxide semiconductor layer of the first active layer may be made of the same material as the first oxide semiconductor layer of the second active layer.

The second oxide semiconductor layer of the first active layer may be made of the same material as the second oxide semiconductor layer of the second active layer and may have the same crystalline structure.

The first oxide semiconductor layer of the first active layer, the first oxide semiconductor layer of the second active layer, and the third oxide semiconductor layer of the second active layer include at least one of an IZO (InZnO)-based, an IGZO (InGaZnO)-based, an IGZTO (InGaZnSnO)-based, a GZTO (GaZnSnO)-based, and a GZO (GaZnSnO)-based oxide semiconductor material, and the second oxide semiconductor layer of the first active layer and the second oxide semiconductor layer of the second active layer may include at least one of an IZO (InZnO)-based oxide semiconductor material, in which the concentration of In is 50% or more compared to the total concentration of In and Zn, an IGO (InGaO)-based oxide semiconductor material, in which the concentration of In is 70% or more compared to the total concentration of In and Ga, an IGZO (InGaZnO)-based oxide semiconductor material, in which the concentration of In is 50% or more compared to the total concentration of In, Ga, and Zn, an ITO (InSnO)-based oxide semiconductor material, in which the concentration of In is 80% or more compared to the total concentration of In and Sn, an IGZTO (InGaZnSnO)-based oxide semiconductor material, in which the sum of concentration of In and Sn is 45% or more compared to the total concentration of In, Ga, Zn, and Sn, and an ITZO (InSnZnO)-based oxide semiconductor material, in which the sum of concentration of In and Sn is 45% or more compared to the total concentration of In, Sn, Zn based on atomic number.

Each of the second oxide semiconductor layer of the first active layer and the second oxide semiconductor layer of the second active layer may further include a dopant doped into the oxide semiconductor material, and the dopant may include at least one of beryllium (Be), boron (B), carbon (C), aluminum (Al), silicon (Si), iron (Fe), calcium (Ca), tin (Sn), titanium (Ti), tantalum (Ta), vanadium (V), yttrium (Y), zirconium (Zr), hafnium (Hf), lanthanum (La), and germanium (Ge).

The dopant included in the second oxide semiconductor layer of the first active layer may have a content of 0.1 to 10 atomic % based on the total number of atoms of the second oxide semiconductor layer of the first active layer, and the dopant included in the second oxide semiconductor layer of the second active layer may have a content of 0.1 to 10 atomic % based on the total number of atoms of the second oxide semiconductor layer of the second active layer.

The first oxide semiconductor layer of the first active layer and the first oxide semiconductor layer of the second active layer may have a thickness of 1 to 10 nm, the second oxide semiconductor layer of the first active layer and the second oxide semiconductor layer of the second active layer may have a thickness of 10 to 50 nm, and the third oxide semiconductor layer of the second active layer may have a thickness of 1 to 20 nm.

The second oxide semiconductor layer of the first active layer and the second oxide semiconductor layer of the second active layer may have at least one of a (400) crystal plane, a (222) crystal plane, a (220) crystal plane, a (311) crystal plane and a (0016) crystal plane.

The second oxide semiconductor layer of the first active layer and the second oxide semiconductor layer of the second active layer may have at least one of a Cubic crystal structure, a Bixbyite crystal structure, a Spinel crystal structure, and a hexagonal crystal structure.

The second oxide semiconductor layer of the first active layer and the second oxide semiconductor layer of the second active layer may include crystal grains having a particle diameter of 3 to 500 nm.

The first active layer includes a third oxide semiconductor layer disposed between the first oxide semiconductor layer and the second oxide semiconductor layer of the first active layer and having a crystalline structure, and a fourth oxide semiconductor layer disposed on the second oxide semiconductor layer of the first active layer and having a crystalline structure, and the second active layer includes a fourth oxide semiconductor layer disposed between the first oxide semiconductor layer and the second oxide semiconductor layer of the second active layer and having a crystalline structure, and a fifth oxide semiconductor layer disposed between the second oxide semiconductor layer and the third oxide semiconductor layer of the second active layer and having a crystalline structure.

The third oxide semiconductor layer of the first active layer may be made of the same material as the first oxide semiconductor layer of the first active layer, the fourth oxide semiconductor layer of the second active layer may be made of the same material as the first oxide semiconductor layer of the second active layer, and the fifth oxide semiconductor layer of the second active layer may be made of the same material as the third oxide semiconductor layer of the second active layer.

Each of the third oxide semiconductor layer of the first active layer, the fourth oxide semiconductor layer of the first active layer, the fourth oxide semiconductor layer of the second active layer, and the fifth oxide semiconductor layer of the second active layer may have a thickness of 0.1 to 3 nm.

The third oxide semiconductor layer of the first active layer, the fourth oxide semiconductor layer of the first active layer, the fourth oxide semiconductor layer of the second active layer, and the fifth oxide semiconductor layer of the second active layer may have a (009) crystal plane and may have a CAAC crystal structure.

The third oxide semiconductor layer of the first active layer, the fourth oxide semiconductor layer of the first active layer, the fourth oxide semiconductor layer of the second active layer, and the fifth oxide semiconductor layer of the second active layer may include crystal grains having a particle diameter of 1 to 10 nm.

An s-factor of the second thin film transistor may be greater than an s-factor of the first thin film transistor, and a mobility of the first thin film transistor may be greater than a mobility of the second thin film transistor.

Another embodiment of the present disclosure provides a manufacturing method of the thin film transistor substrate including preparing a base substrate placed in the first area and the second area; forming a first active layer on the base substrate placed in the first area and forming a second active layer on the base substrate placed in the second area; forming a first gate electrode and a second gate electrode to at least partially overlap the first active layer and the second active layer, respectively. Forming the first active layer and the second active layer includes stacking the first oxide semiconductor material layer, the second oxide semiconductor material layer, and the third oxide semiconductor material layer on the base substrate in order; patterning the first oxide semiconductor material layer, the second oxide semiconductor material layer, and the third oxide semiconductor material layer to form a first active pattern and a second active pattern including a first oxide semiconductor pattern layer, a second oxide semiconductor pattern layer, and a third oxide semiconductor pattern layer, respectively; heat-treating the first active pattern and the second active pattern; and wet etching the third oxide semiconductor pattern layer of the first active pattern using the photoresist material layer, the photoresist material layer overlaps the second active pattern disposed in the second area and does not overlap the first active pattern disposed in the first area.

The first oxide semiconductor material layer, the second oxide semiconductor material layer, and the third oxide semiconductor material layer are formed by sputtering deposition, and when the second oxide semiconductor material layer is formed, the sputtering deposition may be performed at a temperature of 100 to 300° C., and when the first oxide semiconductor material layer and the third oxide semiconductor material layer are formed, the sputtering deposition may be performed at a temperature of 15 to less than 100° C.

The step of heat-treating the first active pattern and the second active pattern may be performed at a temperature of 350 to 450° C.

Another embodiment of the present disclosure provides a display apparatus including the thin film transistor substrate.

It may include a gate driver on the base substrate, and the gate driver may include the first thin film transistor.

It includes a gate driver and a pixel driving circuit on the base substrate, and the first thin film transistor may be included in the gate driver or may be a switching transistor of the pixel driving circuit.

An embodiment of the present disclosure provides a thin film transistor including an active layer, and a gate electrode spaced apart from the active layer and overlapping at least part of the active layer, wherein the active layer includes a first oxide semiconductor layer, a second oxide semiconductor layer on the first oxide semiconductor layer, and a third oxide semiconductor layer on the second oxide semiconductor layer, the first oxide semiconductor layer and the third oxide semiconductor have an amorphous structure, and the second oxide semiconductor layer has a crystalline structure.

The first oxide semiconductor layer and the third oxide semiconductor layer may include at least one of an IZO (InZnO)-based, an IGZO (InGaZnO)-based, an IGZTO (InGaZnSnO)-based, a GZTO (GaZnSnO)-based, and a GZO (GaZnSnO)-based oxide semiconductor material, and the second oxide semiconductor layer may include at least one of an IZO (InZnO)-based oxide semiconductor material, in which the concentration of In is 50% or more compared to the total concentration of In and Zn, an IGO (InGaO)-based oxide semiconductor material, in which the concentration of In is 70% or more compared to the total concentration of In and Ga, an IGZO (InGaZnO)-based oxide semiconductor material, in which the concentration of In is 50% or more compared to the total concentration of In, Ga, and Zn, an ITO (InSnO)-based oxide semiconductor material, in which the concentration of In is 80% or more compared to the total concentration of In and Sn, an IGZTO (InGaZnSnO)-based oxide semiconductor material, in which the sum of concentration of In and Sn is 45% or more compared to the total concentration of In, Ga, Zn, and Sn, and an ITZO (InSnZnO)-based oxide semiconductor material, in which the sum of concentration of In and Sn is 45% or more compared to the total concentration of In, Sn, Zn based on atomic number.

The second oxide semiconductor layer may further include a dopant doped into the oxide semiconductor material, and the dopant may include at least one of beryllium (Be), boron (B), carbon (C), aluminum (Al), silicon (Si), iron (Si), calcium (Ca), tin (Sn), titanium (Ti), tantalum (Ta), vanadium (V), yttrium (Y), zirconium (Zr), hafnium (Hf), lanthanum (La), and germanium (Ge).

The dopant included in the second oxide semiconductor layer may have a content of 0.1 to 10 atomic % based on the total number of atoms in the second oxide semiconductor layer.

The first oxide semiconductor layer may have a thickness of 1 to 10 nm, the second oxide semiconductor layer may have a thickness of 10 to 50 nm, and the third oxide semiconductor layer may have a thickness of 1 to 20 nm.

The second oxide semiconductor layer may have at least one of a (400) crystal plane, a (222) crystal plane, a (220) crystal plane, a (311) crystal plane, and a (0016) crystal plane.

The second oxide semiconductor layer may have at least one of a Cubic crystal structure, a Bixbyite crystal structure, a Spinel crystal structure, and a Hexagonal crystal structure.

The second oxide semiconductor layer may include a crystal grain having a particle diameter of about 3 nm to about 500 nm.

The active layer may further include a fourth oxide semiconductor layer disposed between the first oxide semiconductor layer and the second oxide semiconductor layer and having a crystalline structure, and a fifth oxide semiconductor layer disposed between the second oxide semiconductor layer and the third oxide semiconductor layer and having a crystalline structure.

The fourth oxide semiconductor layer may be made of the same material as the first oxide semiconductor layer, and the fifth oxide semiconductor layer may be made of the same material as the third oxide semiconductor layer.

Each of the fourth oxide semiconductor layer and the fifth oxide semiconductor layer may have a thickness of 0.1 to 3 nm.

The fourth oxide semiconductor layer and the fifth oxide semiconductor layer may have a (009) crystal plane and may have a CAAC crystal structure.

The fourth oxide semiconductor layer and the fifth oxide semiconductor layer may include crystal grains having a particle diameter of 1 to 10 nm.

### BRIEF DESCRIPTION OF THE SEVERAL VIEWS OF THE DRAWINGS

The above and other objects, features and other advantages of the present disclosure will be more clearly understood from the following detailed description taken in conjunction with the accompanying drawings, in which:

FIG. 1 is a cross-sectional view of a thin film transistor substrate according to an embodiment of the present disclosure.

FIG. 2 is a cross-sectional view of a thin film transistor substrate according to another embodiment of the present disclosure.

FIG. 3 is a photograph of an oxide semiconductor layer having a crystalline structure according to another embodiment of the present disclosure.

FIGS. 4A to 4H are manufacturing process diagrams of a thin film transistor substrate according to another embodiment of the present disclosure.

FIG. 5 is a partial cross-sectional view of a display apparatus according to another embodiment of the present disclosure.

FIG. 6 is a cross-sectional view of a thin film transistor according to an embodiment of the present disclosure.

FIG. 7 is a cross-sectional view of a thin film transistor according to another embodiment of the present disclosure.

FIG. 8 is a schematic view of a display apparatus according to another embodiment of the present disclosure.

FIG. 9 is a schematic diagram for a shift register.

FIG. 10 is a circuit diagram of an embodiment of a stage provided in a shift register of FIG. 9.

FIG. 11 is a circuit diagram of any one pixel P of FIG. 8.

FIG. 12 is a plan view of the pixel of FIG. 11.

FIG. 13 is a cross-sectional view taken along line I-I′ of FIG. 12.

### DETAILED DESCRIPTION

Advantages and features of the present disclosure and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete and will fully convey the scope of the present disclosure to those skilled in the art.

A shape, a size, a ratio, an angle and a number disclosed in the drawings for describing embodiments of the present disclosure are merely an example and thus, the present disclosure is not limited to the illustrated details. Like reference numerals refer to like elements throughout the specification. In the following description, when the detailed description of the relevant known function or configuration is determined to unnecessarily obscure the important point of the present disclosure, the detailed description will be omitted.

In a case where ‘comprise,’ ‘have’ and ‘include’ described in the present disclosure are used, another portion may be added unless ‘only˜’ is used. The terms of a singular form may include plural forms unless referred to the contrary.

In construing an element, the element is construed as including an error band although there is no explicit description.

In describing a position relationship, for example, when the position relationship is described as ‘upon˜,’ ‘above˜,’ ‘below˜’ and ‘next to˜,’ one or more portions may be disposed between two other portions unless ‘just’ or ‘direct’ is used.

Spatially relative terms such as “below,” “beneath,” “lower,” “above,” and “upper” may be used herein to easily describe a relationship of one element or elements to another element or elements as illustrated in the drawings. It will be understood that these terms are intended to encompass different orientations of the device in addition to the orientation depicted in the drawings. For example, if the device illustrated in the figure is reversed, the device described to be arranged “below,” or “beneath” another device may be arranged “above” another device. Therefore, an exemplary term “below or beneath” may include “below or beneath” and “above” orientations. Likewise, an exemplary term “above” or “on” may include “above” and “below or beneath” orientations.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc., may be used herein to describe various elements, these elements should not be limited by these terms. These terms are only used to distinguish one element from another. For example, a first element could be termed a second element, and, similarly, a second element could be termed a first element, without departing from the scope of the present disclosure.

It should be understood that the term “at least one” includes all combinations related with any one item. For example, “at least one among a first element, a second element and a third clement” may include all combinations of two or more elements selected from the first, second and third elements as well as each element of the first, second and third elements. A range in the description, unless expressly stated otherwise, includes the boundary point(s) thereof.

Features of various embodiments of the present disclosure may be partially or overall coupled to or combined with each other and may be variously inter-operated with each other and driven technically as those skilled in the art can sufficiently understand. The embodiments of the present disclosure may be carried out independently from each other or may be carried out together in a co-dependent relationship.

In the addition of reference numerals to the components of each drawing describing embodiments of the present disclosure, the same components can have the same sign as can be displayed on the other drawings.

In the embodiments of the present disclosure, a source electrode and a drain electrode are referred to for convenience of description, and the source electrode and the drain electrode may be interchanged. The source electrode may be the drain electrode and vice versa. In addition, the source electrode of any one embodiment may be a drain electrode in another embodiment, and the drain electrode of any one embodiment may be a source electrode in another embodiment.

In some embodiments of the present disclosure, for convenience of description, a source area is referred to separately from a source electrode, and a drain area is referred to separately from a drain electrode, but embodiments of the present disclosure are not limited thereto. The source area may be the source electrode, and the drain area may be the drain electrode. In addition, the source area may be the drain electrode, and the drain area may be the source electrode.

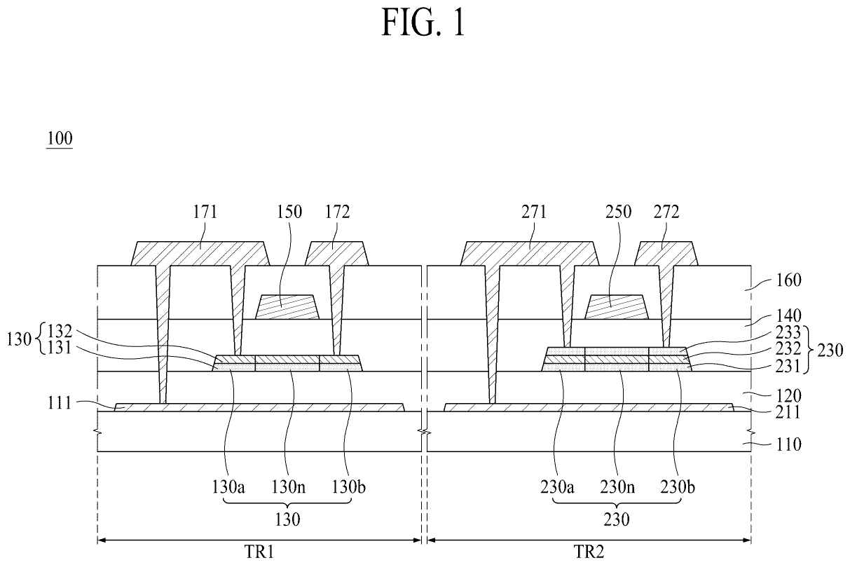

FIG. 1 is a cross-sectional view of a thin film transistor substrate 100 according to an embodiment of the present disclosure.

The thin film transistor substrate 100 according to an embodiment of the present disclosure includes the first thin film transistor TR1 and the second thin film transistor TR2. Specifically, referring to FIG. 1, the thin film transistor substrate 100 includes the first thin film transistor TR1 and the second thin film transistor TR2 on the base substrate 110.

The first thin film transistor TR1 includes the first active layer 130 and a first gate electrode 150 spaced apart from the first active layer 130 and at least partially overlapping the first active layer 130.

The second thin film transistor TR2 includes the second active layer 230 and the second gate electrode 250 spaced apart from the second active layer 230 and at least partially overlapping the second active layer 230.

Glass or plastic may be used as the base substrate 110. As the plastic, a transparent plastic having a flexible characteristic, for example, polyimide, may be used. Referring to FIG. 1, the base substrate 110 on which the first thin film transistor TR1 is disposed and the base substrate 110 on which the second thin film transistor TR2 is disposed may be integrally formed with each other.

Light blocking layers 111 and 211 may be disposed on the base substrate 110. The light blocking layers 111 and 211 block light incident from the base substrate 110 to protect the first active layer 130 and the second active layer 230. When another structure serves as a light blocking function, the light blocking layers 111 and 211 may be omitted.

According to an embodiment of the present disclosure, a buffer layer 120 may be disposed on the base substrate 110 and the light blocking layers 111 and 211.

The buffer layer 120 has insulating properties and protects the first active layer 130 and the second active layer 230. The buffer layer 120 may include at least one of silicon oxide (SiOx), silicon nitride (SiNx), and metal oxide having insulating properties.

The first active layer 130 and the second active layer 230 may be disposed on the buffer layer 120.

Each of the first active layer 130 and the second active layer 230 includes an oxide semiconductor material. According to an embodiment of the present disclosure, the first active layer 130 and the second active layer 230 are oxide semiconductor layers made of an oxide semiconductor material. The first active layer 130 and the second active layer 230 made of an oxide semiconductor material include metal and oxygen (O).

In addition, each of the first active layer 130 and the second active layer 230 may include at least one layer having a crystalline structure.

According to an embodiment of the present disclosure, the first active layer 130 includes a first oxide semiconductor layer 131 and a second oxide semiconductor layer 132. The second oxide semiconductor layer 132 may be disposed on the first oxide semiconductor layer 131.

Furthermore, according to an embodiment of the present disclosure, the second active layer 230 includes a first oxide semiconductor layer 231, a second oxide semiconductor layer 232, and a third oxide semiconductor layer 233. The second oxide semiconductor layer 232 is disposed on the first oxide semiconductor layer 231, and the third oxide semiconductor layer 233 is disposed on the second oxide semiconductor layer 232.

According to an embodiment of the present disclosure, the first oxide semiconductor layer 131 of the first active layer 130 may have an amorphous structure, and the second oxide semiconductor layer 132 may have a crystalline structure. Furthermore, the first oxide semiconductor layer 231 and the third oxide semiconductor layer 233 of the second active layer 230 may have an amorphous structure, and the second oxide semiconductor layer 232 may have a crystalline structure. According to an embodiment of the present disclosure, the crystalline structure and the amorphous structure are referred to based on the content of a crystal grain included in the oxide semiconductor layer. More specifically, according to an embodiment of the present disclosure, the crystalline structure and the amorphous structure are distinguished from each other based on a ratio of crystal grains having a particle diameter of 1 nm or more.

According to an embodiment of the present disclosure, a crystal grain refers to an aggregate of atoms having a regular arrangement. In the crystal grain, atoms have a regular arrangement. A mass in which internal atoms have a regular arrangement refers to a crystal grain.

According to an embodiment of the present disclosure, the arrangement state of atoms may be confirmed by a cross-sectional image taken by a transmission electron microscope (TEM). A cross-sectional image of the oxide semiconductor layer may be obtained by a transmission electron microscope (TEM), and in the cross-sectional image of the oxide semiconductor layer, a crystal grain has a shape of one aggregate or two-dimensional mass having a boundary.

A crystal grain has a particle diameter. In a cross-sectional image photographed by a transmission electron microscope (TEM), the length of the longest axis of the crystal grain is referred to as the particle diameter of the crystal grain.

According to an embodiment of the present disclosure, in the cross-sectional image of the oxide semiconductor layer photographed by a transmission electron microscope (TEM), when the ratio of crystal grain having a particle diameter of 1 nm or more is 50% or more of the total cross-sectional area, the oxide semiconductor layer refers to having a crystalline structure. In addition, in the cross-sectional image of the oxide semiconductor layer photographed by a transmission electron microscope (TEM), when the ratio of crystal grain having a particle diameter of 1 nm or more is 10% or less of the total cross-sectional area, the oxide semiconductor layer refers to having an amorphous structure.

According to an embodiment of the present disclosure, the first oxide semiconductor layer 131 of the first active layer 130, the first oxide semiconductor layer 231, and the third oxide semiconductor layer 233 of the second active layer 230 have an amorphous structure. Specifically, in the cross-sectional images of the first oxide semiconductor layers 131 and 231 and the third oxide semiconductor layer 233 captured by the transmission electron microscope (TEM), the ratio of crystal grain having a particle diameter of 1 nm or more may be 10% or less of the total cross-sectional rea. More specifically, in the cross-sectional images of the first oxide semiconductor layers 131 and 231 and the third oxide semiconductor layer 233 captured by the transmission electron microscope (TEM), the ratio of the crystal grain having a particle diameter of 5 nm to 10nm may be 10% or less of the total cross-sectional area.

The first oxide semiconductor layer 131 of the first active layer 130, the first oxide semiconductor layer 231, and the third oxide semiconductor layer 233 of the second active layer 230 may include at least one of, for example, an IZO (InZnO)-based, an IGZO (InGaZnO)-based, an IGZTO (InGaZnSnO)-based, a GZTO (GaZnSnO)-based, and a GZO (GaZnO)-based oxide semiconductor material. More specifically, the first oxide semiconductor layer 131 of the first active layer 130, the first oxide semiconductor layer 231, and the third oxide semiconductor layer 233 of the second active layer 230 may include an IGZO (InGaZnO)-based oxide semiconductor material. In some embodiments, the first oxide semiconductor layer 131 of the first active layer 130, the first oxide semiconductor layer 231 of the second active layer 230, and the third oxide semiconductor layer 233 of the second active layer 230 may include an IGZO (InGaZnO)-based oxide semiconductor material.

According to an embodiment of the present disclosure, the first oxide semiconductor layer 131 of the first active layer 130 and the first oxide semiconductor layer 231 of the second active layer 230 may have a thickness of 1 to 10 nm.

When the thickness of the first oxide semiconductor layers 131 and 231 is less than 1 nm, it is not easy to etch the first oxide semiconductor layers 131 and 231 due to the excessively thin thickness, and thus patterning of the first oxide semiconductor layers 131 and 231 may not be performed. As a result, difficulties in forming the first active layer 130 and the second active layer 230 may occur.

The first oxide semiconductor layers 131 and 231 serve to improve the etchability of the second oxide semiconductor layers 132 and 232. Therefore, the first oxide semiconductor layer 131 can be made thin. When the thickness of the first oxide semiconductor layers 131 and 231 exceeds 10 nm, the first active layer 130 and the second active layer 230 may be unnecessarily thickened, which may be disadvantageous in thin film formation.

According to an embodiment of the present disclosure, the first oxide semiconductor layer 131 of the first active layer 130 may be formed of the same material as the first oxide semiconductor layer 231 of the second active layer 230. Specifically, the first oxide semiconductor layers 131 and 231 may be formed by the same process. Although a structure in which the first oxide semiconductor layers 131 and 231 are disposed on the same layer is illustrated in FIG. 1, an embodiment of the present disclosure is not limited thereto, and may be disposed on another layer.

According to an embodiment of the present disclosure, the second oxide semiconductor layers 132 and 232 are disposed on the first oxide semiconductor layers 131 and 231, respectively. Specifically, the second oxide semiconductor layer 132 of the first active layer 130 is disposed on the first oxide semiconductor layer 131 of the first active layer 130, and the second oxide semiconductor layer 232 of the second active layer 230 is disposed on the first oxide semiconductor layer 231 of the second active layer 230. By adjusting the composition and manufacturing conditions during the manufacturing process of the second oxide semiconductor layers 132 and 232, the second oxide semiconductor layers 132 and 232 may have a crystalline structure. For example, in order to form the crystalline structure, the second oxide semiconductor layers 132 and 232 may be formed by sputter deposition and a heat treatment step performed at a temperature of 350 to 450° C. In this case, sputter deposition may be performed at a temperature of 100 to 300° C.

According to an embodiment of the present disclosure, the second oxide semiconductor layers 132 and 232 have a crystalline structure. Specifically, in the cross-sectional image of the second oxide semiconductor layers 132 and 232 photographed by the transmission electron microscope (TEM), the ratio of crystal grains having a particle diameter of 1 nm or more may be 50% or more of the total cross-sectional area. More specifically, in the cross-sectional image of the second oxide semiconductor layers 132 and 232 photographed by the transmission electron microscope (TEM), the ratio of crystal grain having a particle diameter of 5 nm to 10 nm may be 50% or more of the total cross-sectional area.

According to an embodiment of the present disclosure, as the second oxide semiconductor layers 132 and 232 having crystallinity are formed on the first oxide semiconductor layers 131 and 231 having the amorphous structure, crystal grains having relatively small particle sizes may be formed on the second oxide semiconductor layers 132 and 232. As a result, the second oxide semiconductor layers 132 and 232 may be easily etched while having a crystalline structure.

By forming the second oxide semiconductor layers 132 and 232 having crystal formation characteristics on the first oxide semiconductor layers 131 and 231 having the amorphous structure, a crystalline structure may be formed on the second oxide semiconductor layers 132 and 232 without undergoing a rigorous crystallization process control, for example, a heat treatment process through strict temperature control. In this case, a large number of crystal grains having small particle diameters may be formed on the second oxide semiconductor layers 132 and 232.

The second oxide semiconductor layers 132 and 232 may include at least one of an IZO (InZnO)-based oxide semiconductor material, in which the concentration of In is 50% or more compared to the total concentration of In and Zn, an IGO (InGaO)-based oxide semiconductor material, in which the concentration of In is 70% or more compared to the total concentration of In and Ga, an IGZO (InGaZnO)-based oxide semiconductor material, in which the concentration of In is 50% or more compared to the total concentration of In, Ga, and Zn, an ITO (InSnO)-based oxide semiconductor material, in which the concentration of In is 80% or more compared to the total concentration of In and Sn, an IGZTO (InGaZnSnO)-based oxide semiconductor material, in which the sum of concentration of In and Sn is 45% or more compared to the total concentration of In, Ga, Zn, and Sn, and an ITZO (InSnZnO)-based oxide semiconductor material, in which the sum of concentration of In and Sn is 45% or more compared to the total concentration of In, Sn, Zn based on atomic number. In some embodiments, the second oxide semiconductor layers 132 and 232 may include an IZO (InZnO)-based oxide semiconductor material, in which the concentration of In is 50% or more compared to the total concentration of In and Zn.

For example, in the case of an IZO (InZnO)-based oxide semiconductor material, the ratio of In to Zn may be 5:5, 6:4, and 7:3. In addition, in the case of an IGO (InGaO)-based oxide semiconductor material, the ratio of In to Ga may be 7:3, 8:2, and 9:1.

According to an embodiment of the present disclosure, the second oxide semiconductor layer 132 of the first active layer 130 and the second oxide semiconductor layer 232 of the second active layer 230 may be formed of the same material. Specifically, the second oxide semiconductor layer 132 of the first active layer 130 and the second oxide semiconductor layer 232 of the second active layer 230 may have the same crystal structure.

According to an embodiment of the present disclosure, the second oxide semiconductor layers 132 and 232 may be doped with a dopant. For example, the dopant may be doped into the second oxide semiconductor layers 132 and 232 by an ion implantation method. Accordingly, according to an embodiment of the present disclosure, the second oxide semiconductor layers 132 and 232 may further include a dopant doped into an oxide semiconductor material. The dopant may include at least one of beryllium (Be), boron (B), carbon (C), aluminum (Al), silicon (Si), iron (Fc), calcium (Ca), tin (Sn), titanium (Ti), tantalum (Ta), vanadium (V), yttrium (Y), zirconium (Zr), hafnium (Hf), lanthanum (La), and germanium (Ge). Specifically, the second oxide semiconductor layers 132 and 232 may be formed of an IGO (InGaO)-based oxide semiconductor material doped with at least one of beryllium (Be), boron (B), carbon (C), aluminum (Al), silicon (Si), iron (Fe), calcium (Ca), tin (Sn), titanium (Ti), tantalum (Ta), vanadium (V), yttrium (Y), zirconium (Zr), hafnium (Hf), lanthanum (La), and germanium (Ge).

The dopant may be disposed in a crystal grain or at the boundary between crystal grains. Even if a dopant is contained in an assembly of atoms, when atoms other than the dopant are regularly arranged in an assembly of atoms, the assembly of these atoms is called a crystal grain.

When the second oxide semiconductor layers 132 and 232 are doped with a dopant, defects in particles of the second oxide semiconductor layers 132 and 232 may be prevented so that the second oxide semiconductor layers 132 and 232 may have a stable crystal structure, and crystal grains having a particle diameter of 3 to 500 nm may be easily formed on the second oxide semiconductor layers 132 and 232. When at least one of beryllium (Be), boron (B), carbon (C), aluminum (Al), silicon (Si), iron (Fc), calcium (Ca), tin (Sn), titanium (Ti), tantalum (Ta), vanadium (V), yttrium (Y), zirconium (Zr), hafnium (Hf), lanthanum (La), and germanium (Ge) is doped into the second oxide semiconductor layers 132 and 232, crystal grains may be easily formed. Specifically, due to the dopant having a high bonding force with oxygen (O), which is a constituent element of the oxide semiconductor material, the second oxide semiconductor layers 132 and 232 may stably have a crystal structure, and crystal grains having a particle diameter of 3 to 500 nm may be easily formed on the second oxide semiconductor layers 132 and 232. As a result, the second oxide semiconductor layers 132 and 232 may have etching characteristics, and may have excellent resistance to defects.

According to an embodiment of the present disclosure, beryllium (Be), boron (B), carbon (C), aluminum (Al), silicon (Si), iron (Fe), calcium (Ca), tin (Sn) titanium (Ti), tantalum (Ta), vanadium (V), yttrium (Y), zirconium (Zr), hafnium (Hf), lanthanum (La), and germanium (Ge) may serve as crystal stabilization stabilizers for controlling crystallization conditions, grain sizes, or crystallization states of the second oxide semiconductor layers 132 and 232. Furthermore, the dopant having metal characteristics may serve as an electrical stabilizer for controlling changes in electrical characteristics of the second oxide semiconductor layers 132 and 232. Specifically, beryllium (Be), boron (B), carbon (C), aluminum (Al), silicon (Si), iron (Fe), calcium (Ca), tin (Sn) titanium (Ti), tantalum (Ta), vanadium (V), yttrium (Y), zirconium (Zr), hafnium (Hf), lanthanum (La), and germanium (Ge) doped into oxide semiconductor materials can be controlled so that crystal grains can be effectively formed in the second oxide semiconductor layers 132 and 232, and the electrical properties of the second oxide semiconductor layers 132 and 232 can be maintained stably.

The dopant included in the second oxide semiconductor layers 132 and 232 may have a content of 0.1 to 10 atomic % based on the total number of atoms of the second oxide semiconductor layers 132 and 232. Specifically, the dopant included in the second oxide semiconductor layer 132 of the first active layer may have a content of 0.1 to 10 atomic % based on the total number of atoms of the second oxide semiconductor layer 132, and the dopant included in the second oxide semiconductor layer 232 of the second active layer may have a content of 0.1 to 10 atomic % based on the total number of atoms of the second oxide semiconductor layer 232.

When the dopant included in each of the second oxide semiconductor layers 132 and 232 has a content of less than 0.1 atomic % based on the total number of atoms in each of the second oxide semiconductor layers 132 and 232, a problem that it cannot serve as a crystal stabilizer for controlling crystallization conditions, grain size, or crystallization state occurs.

In addition, if the dopant included in each of the second oxide semiconductor layers 132 and 232 has a content exceeding 10 atomic % based on the total number of atoms in each of the second oxide semiconductor layers 132 and 232, the activation energy for the second oxide semiconductor layers 132 and 232 to crystallize may increase, which may require a very high heat treatment temperature, and the dopant included in the second oxide semiconductor layers 132 and 232 may interfere with the lattice arrangement, making it difficult to secure crystallinity or a problem of amorphization. As a result, the oxide semiconductor may not have properties as a semiconductor, and electrical properties may be deteriorated.

According to an embodiment of the present disclosure, the second oxide semiconductor layers 132 and 232 may serve as a main channel layer of the active layers 130 and 230. To this end, the second oxide semiconductor layers 132 and 232 may have a thickness of 10 to 50 nm. When the thickness of the second oxide semiconductor layers 132 and 232 is less than 10 nm, crystal growth may not be smooth, and current flow through the second oxide semiconductor layers 132 and 232 serving as a main channel layer may not be smooth. On the other hand, when the thickness of the second oxide semiconductor layers 132 and 232 exceeds 50 nm, the active layers 130 and 230 may become thick, which may be disadvantageous in forming a thin film.

According to an embodiment of the present disclosure, the second oxide semiconductor layers 132 and 232 may have at least one of a (400) crystal plane, a (222) crystal plane, a (220) crystal plane, a (311) crystal plane, and a (0016) crystal plane.

According to an embodiment of the present disclosure, the second oxide semiconductor layers 132 and 232 may have at least one of a Cubic crystal structure, a Bixbyite crystal structure, a Spinel crystal structure, and a Hexagonal crystal structure.

In the second oxide semiconductor layers 132 and 232 having a crystalline structure, defects in particles are prevented, thereby preventing defects or damage during a manufacturing process or during driving. As a result, the second oxide semiconductor layers 132 and 232 may have excellent reliability. The first thin film transistor TR1 and the second thin film transistor TR2 including the second oxide semiconductor layers 132 and 232 have excellent reliability characteristics due to a reduction in defects, and at the same time may have high mobility characteristics.

According to an embodiment of the present disclosure, the second thin film transistor TR2 may further include a third oxide semiconductor layer 233.

The third oxide semiconductor layer 233 serves to protect the second oxide semiconductor layer 232 of the second active layer 230 and may have an amorphous structure.

The third oxide semiconductor layer 233 of the second active layer 230 may include at least one of an IZO (InZnO)-based, an IGZO (InGaZnO)-based, an IGZTO (InGaZnSnO)-based, a GZTO (GaZnSnO)-based, and a GZO (GaZnSnO)-based oxide semiconductor material. In detail, the third oxide semiconductor layer 233 may include an IGZO (InGaZnO)-based oxide semiconductor material.

According to an embodiment of the present disclosure, the third oxide semiconductor layer 233 of the second active layer 230 may have a thickness of 1 to 20 nm.

When the thickness of the third oxide semiconductor layer 233 is less than 1 nm, it is not easy to etch the third oxide semiconductor layer 233 due to an excessively thin thickness, and thus patterning of the third oxide semiconductor layer 233 may not be performed. As a result, difficulties in forming the second active layer 230 may occur.

When the thickness of the third oxide semiconductor layer 233 exceeds 20 nm, the thickness of the second active layer 230 may be unnecessarily thick, which may be disadvantageous in forming a thin film.

By adjusting the composition and manufacturing conditions during the manufacturing process of the third oxide semiconductor layer 233, the third oxide semiconductor layer 233 having an amorphous structure may be formed.

According to an embodiment of the present disclosure, the first thin film transistor TR1 may include a first active layer 130 having a double layer structure (amorphous-crystalline), and the second thin film transistor TR2 may include a second active layer 230 having a triple layer structure (amorphous-crystalline-amorphous).

When the first active layer 130 of the first thin film transistor TR1 has a double layer structure (amorphous-crystalline), the second oxide semiconductor layer 132 having the crystalline structure may serve as a channel layer, and when the second active layer 230 of the second thin film transistor TR2 has a triple layer structure (amorphous-crystalline-amorphous), the second oxide semiconductor layer 232 having the crystalline structure and the third oxide semiconductor layer 233 having the amorphous structure may serve as a channel layer.

In this case, compared to the second thin film transistor TR2, in which only the second oxide semiconductor layer 132 having a crystalline structure serves as a main channel layer, the first thin film transistor TR1 does not have an amorphous structure disposed in the main channel layer, and thus the carrier mobility (“mobility”) may be high.

On the other hand, in the case of the second thin film transistor TR2, in which both the second oxide semiconductor layer 232 having the crystalline structure and the third oxide semiconductor layer 233 having the amorphous structure serve as the channel layer, the second oxide semiconductor layer 232 having the crystalline structure may serve as the main channel layer. In this case, the third oxide semiconductor layer 233 having the amorphous structure is disposed between the second oxide semiconductor layer 232 serving as the main channel layer and the gate insulating layer 140, and a smaller amount of electrons is trapped between the second active layer 230 and the gate insulating layer 140. More specifically, a smaller amount of electrons may be trapped at the interface between the second active layer 230 and the gate insulating layer 140. As a result, the second thin film transistor TR2 may have higher reliability than that of the first thin film transistor TR1. More specifically, the s-factor of the second thin film transistor TR2 may be greater than the s-factor of the first thin film transistor TR1.

In order for a display apparatus driven by a current to have excellent gray scale expression capability, it is advantageous as the s-factor of a thin film transistor driving a pixel of the display apparatus increases.

The sub-threshold swing (s-factor) represents the reciprocal value of the slope of the graph in the threshold voltage (Vth) interval in the drain-source current IDS characteristic graph (not shown) with respect to the gate voltage VG of the thin film transistor. As the s-factor increases, the rate of change of the drain-source current IDS with respect to the gate voltage VG in the threshold voltage (Vth) interval decreases. Accordingly, the ability to express gray scale of a display apparatus driven by such a thin film transistor may be improved.

Specifically, the first thin film transistor TR1 may be placed in the gate driver of the display apparatus that requires excellent current characteristics, and the second thin film transistor TR2 may be placed in the pixel driving circuit of the display apparatus that requires excellent gray scale expression capability.

According to the present disclosure, there is an advantage in that the first active layer 130 of the first thin film transistor TR1 and the second active layer 230 of the second thin film transistor TR2 can be formed through a single process.

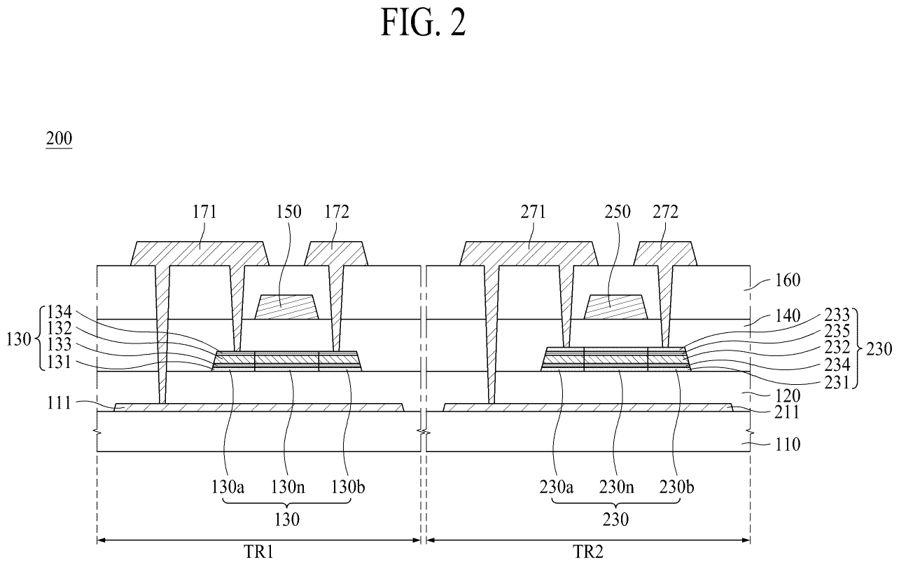

FIG. 2 is a cross-sectional view of a thin film transistor substrate 200 according to another embodiment of the present disclosure. Hereinafter, descriptions of already described components will be omitted to avoid duplication.

According to an embodiment of the present disclosure, the first active layer 130 may further include a third oxide semiconductor layer 133 and a fourth oxide semiconductor layer 134. Further, the second active layer 230 may further include a fourth oxide semiconductor layer 234 and a fifth oxide semiconductor layer 235.

The third oxide semiconductor layer 133 of the first active layer 130 is disposed between the first oxide semiconductor layer 131 and the second oxide semiconductor layer 132 of the first active layer 130, and the fourth oxide semiconductor layer 134 of the first active layer 130 is disposed on the second oxide semiconductor layer 132 of the first active layer 130.

In this case, the third oxide semiconductor layer 133 and the fourth oxide semiconductor layer 134 of the first active layer 130 have a crystalline structure.

The fourth oxide semiconductor layer 234 of the second active layer 230 is disposed between the first oxide semiconductor layer 231 and the second oxide semiconductor layer 232 of the second active layer 230, and the fifth oxide semiconductor layer 235 of the second active layer 230 is disposed between the second oxide semiconductor layer 232 and the third oxide semiconductor layer 233 of the second active layer 230.

In this case, the fourth oxide semiconductor layer 234 and the fifth oxide semiconductor layer 235 of the second active layer 230 have a crystalline structure.

By adjusting manufacturing conditions during the manufacturing process of the third oxide semiconductor layers 133, the fourth oxide semiconductor layers 134 and 234, and the fifth oxide semiconductor layer 235, the third oxide semiconductor layers 133, the fourth oxide semiconductor layers 134 and 234 and the fifth oxide semiconductor layer 235 may have a crystalline structure. For example, in order to form a crystalline structure, a step of performing heat treatment during formation of the first active layer 130 and the second active layer 230 may be included. In this case, the heat treatment may be performed at a temperature of 350 to 450° C.

According to an embodiment of the present disclosure, the third oxide semiconductor layer 133, the fourth oxide semiconductor layers 134 and 234, and the fifth oxide semiconductor layer 235 may include at least one of an IZO (InZnO)-based, an IGZO (InGaZnO)-based, an IGZTO (InGaZnSnO)-based, a GZTO (GaZnSnO)-based, and a GZO (GaZnSnO)-based oxide semiconductor material. For example, the third oxide semiconductor layer 133, the fourth oxide semiconductor layers 134 and 234, and the fifth oxide semiconductor layer 235 may include an IGZO (InGaZnO)-based oxide semiconductor material.

According to an embodiment of the present disclosure, the third oxide semiconductor layer 133 of the first active layer 130 may be formed of the same material as the first oxide semiconductor layer 131 of the first active layer 130, the fourth oxide semiconductor layer 234 of the second active layer 230 may be formed of the same material as the first oxide semiconductor layer 231 of the second active layer 230, and the fifth oxide semiconductor layer 235 of the second active layer 230 may be formed of the same material as the third oxide semiconductor layer 233 of the second active layer 230.

When the active layers 130 and 230 are formed, the second oxide semiconductor layers 132 and 232 are crystallized first, and the crystallized second oxide semiconductor layers 132 and 232 act as catalysts for the amorphous oxide semiconductor layers stacked on the upper and lower portions of the second oxide semiconductor layers 132 and 232, thereby forming the crystallized third oxide semiconductor layers 133, the fourth oxide semiconductor layers 134 and 234, and the fifth oxide semiconductor layers 235.

In other words, the crystallized second oxide semiconductor layers 132 and 232 serve as catalysts for the amorphous oxide semiconductor layers stacked on the upper and lower portions of the second oxide semiconductor layers 132 and 232, and the amorphous oxide semiconductor layers stacked on the upper and lower portions of the second oxide semiconductor layers 132 and 232 erode in the direction of the second oxide semiconductor layers 132 and 232 to form the crystallized third oxide semiconductor layers 133, the fourth oxide semiconductor layers 134 and 234, and the fifth oxide semiconductor layer 235.

Accordingly, the third oxide semiconductor layers 133, the fourth oxide semiconductor layers 134 and 234, and the fifth oxide semiconductor layer 235 are layers crystallized by eroding an amorphous structure having high reliability. That is, even if the third oxide semiconductor layer 133, the fourth oxide semiconductor layers 134 and 234, and the fifth oxide semiconductor layer 235 have a crystallized structure, mobility may be slightly lower than that of the second oxide semiconductor layers 132 and 232, and reliability may be high.

According to an embodiment of the present disclosure, the amorphous oxide semiconductor layer formed on the fourth oxide semiconductor layer 134 of the first active layer 130 is removed by wet etching. Accordingly, the first thin film transistor TR1 includes the first active layer 130 having a quadruple layer structure (amorphous-crystalline-crystalline-crystalline), and the second thin film transistor TR2 may include the second active layer 230 having a quintic layer structure (amorphous-crystalline-crystalline-crystalline-amorphous).

In this case, when the thickness of the first oxide semiconductor layer 131 of the first active layer 130 exceeds 5 nm, the side surface of the first oxide semiconductor layer 131 having an amorphous structure may be partially etched by wet etching of the amorphous oxide semiconductor layer formed on the fourth oxide semiconductor layer 134.

When the first active layer 130 of the first thin film transistor TR1 has a quadruple layer structure (amorphous-crystalline-crystalline-crystalline), the second oxide semiconductor layer 132, the third oxide semiconductor layer 133, and the fourth oxide semiconductor layer 134 having the crystalline structure may serve as channel layers, and when the second active layer 230 of the second thin film transistor TR2 has a quintuple film structure (amorphous-crystalline-crystalline-crystalline-amorphous), the second oxide semiconductor layer 232, the fourth oxide semiconductor layer 234, the fifth oxide semiconductor layer 235 having the crystalline structure, and the third oxide semiconductor layer 233 having the amorphous structure may serve as channel layers.

In this case, the first thin film transistor TR1, in which the second oxide semiconductor layer 132, the third oxide semiconductor layer 133, and the fourth oxide semiconductor layer 134 having the crystalline structure serve as the main channel layer, does not have an amorphous structure disposed in the main channel layer compared to the second thin film transistor TR2, and thus mobility may be high.

On the other hand, in the case of the second thin film transistor TR2 in which the second oxide semiconductor layer 232, the fourth oxide semiconductor layer 234, and the fifth oxide semiconductor layer 235 having the crystalline structure and the third oxide semiconductor layer 233 having the amorphous structure all serve as the channel layer, the second oxide semiconductor layer 232, the fourth oxide semiconductor layer 234, and the fifth oxide semiconductor layer 235 having the crystalline structure serve as the main channel layer, and the third oxide semiconductor layer 233 having the amorphous structure is disposed between the fifth oxide semiconductor layer 235 and the gate insulating layer 140 disposed at the top of the main channel layer, and a smaller amount of electrons is trapped between the second active layer 230 and the gate insulating layer 140. As a result, the second thin film transistor TR2 may have higher reliability than that of the first thin film transistor TR1. More specifically, the s-factor of the second thin film transistor TR2 may be greater than the s-factor of the first thin film transistor TR1.

Specifically, the first thin film transistor TR1 may be placed in the gate driver of the display apparatus that requires excellent current characteristics, and the second thin film transistor TR2 may be placed in the pixel driving circuit of the display apparatus that requires excellent gray scale expression capability.

According to an embodiment of the present disclosure, since the first active layer 130 includes the fourth oxide semiconductor layer 134 having high reliability on the second oxide semiconductor layer 132 having high mobility among the main channel layers, the first thin film transistor TR1 may secure high mobility and prevent electron traps to increase reliability.

In addition, according to an embodiment of this disclosure, the second active layer 230 includes the fifth oxide semiconductor layer 235 in which reliability and mobility are simultaneously secured between the second oxide semiconductor layer 232 having high mobility and the third oxide semiconductor layer 233 having high reliability, so that the second thin film transistor TR2 can simultaneously secure mobility and reliability.

In the cross-sectional images of the third oxide semiconductor layer 133, the fourth oxide semiconductor layer 134 of the first active layer 130, and the fourth oxide semiconductor layer 234 and the fifth oxide semiconductor layer 235 of the second active layer 230 captured by the transmission electron microscope (TEM), the ratio of crystal grains having a particle diameter of 1 nm or more may be 50% or more of the entire cross-sectional area. More specifically, in the cross-sectional images of the third oxide semiconductor layer 133, the fourth oxide semiconductor layers 134 and 234, and the fifth oxide semiconductor layer 235 captured by the transmission electron microscope (TEM), the ratio of the crystal grains having a particle diameter of 5 nm to 10 nm may be 50% or more of the entire cross-sectional area.

According to an embodiment of the present disclosure, the third oxide semiconductor layer 133, the fourth oxide semiconductor layer 134 of the first active layer 130, and the fourth oxide semiconductor layer 234 and the fifth oxide semiconductor layer 235 of the second active layer 230 may have (009) crystal planes.

Specifically, the third oxide semiconductor layer 133, the fourth oxide semiconductor layer 134 of the first active layer 130, and the fourth oxide semiconductor layer 234 and the fifth oxide semiconductor layer 235 of the second active layer 230 may have a CAAC crystal structure.

More specifically, the third oxide semiconductor layer 133 and the fourth oxide semiconductor layer 134 of the first active layer 130, the fourth oxide semiconductor layer 234 and the fifth oxide semiconductor layer 235 of the second active layer 230 may have different crystal surfaces and crystal structures from those of the second oxide semiconductor layers 132 and 232.

According to an embodiment of the present disclosure, the third oxide semiconductor layer 133, the fourth oxide semiconductor layer 134 of the first active layer 130, and the fourth oxide semiconductor layer 234 and the fifth oxide semiconductor layer 235 of the second active layer 230 may include crystal grains having a particle diameter of 1 to 10 nm. Specifically, the third oxide semiconductor layer 133, the fourth oxide semiconductor layer 134 of the first active layer 130, and the fourth oxide semiconductor layer 234 and the fifth oxide semiconductor layer 235 of the second active layer 230 may have smaller crystal grains than the second oxide semiconductor layers 132 and 232.

Small crystal grains included in the third oxide semiconductor layer 133 and the fourth oxide semiconductor layer 134 of the first active layer 130, the fourth oxide semiconductor layer 234 and the fifth oxide semiconductor layer 235 of the second active layer 230 may be easily etched compared to huge crystals.

The third oxide semiconductor layer 133 and the fourth oxide semiconductor layer 134 of the first active layer 130, the fourth oxide semiconductor layer 234 and the fifth oxide semiconductor layer 235 of the second active layer 230 consisting of small crystal grains have excellent etching characteristics, and thus may be easily patterned.

According to an embodiment of the present disclosure, the third oxide semiconductor layer 133, the fourth oxide semiconductor layer 134 of the first active layer 130, and the fourth oxide semiconductor layer 234 and the fifth oxide semiconductor layer 235 of the second active layer 230 may have a thickness of 0.1 to 3 nm.

On the other hand, when the thicknesses of the third oxide semiconductor layer 133, the fourth oxide semiconductor layer 134 of the first active layer 130, and the fourth oxide semiconductor layer 234 and the fifth oxide semiconductor layer 235 of the second active layer 230 are less than 0.1 nm, the reliability improvement function capable of suppressing the electron trap may be deteriorated.

When the thicknesses of the third oxide semiconductor layer 133, the fourth oxide semiconductor layer 134 of the first active layer 130, and the fourth oxide semiconductor layer 234 and the fifth oxide semiconductor layer 235 of the second active layer 230 exceed 3 nm, the specific gravity of the film characteristics having lower mobility than those of the second oxide semiconductor layers 132 and 232, which are main channel layers, increases. As a result, there may be a problem that the overall mobility of the thin film transistor is lowered.

The gate insulating layer 140 is disposed on the active layers 130 and 230. The gate insulating layer 140 may include at least one of silicon oxide and silicon nitride, and may include a metal oxide or a metal nitride. The gate insulating layer 140 may have a single layer structure or a multilayer structure. The gate insulating layer 140 may be disposed to cover the entire upper surface of the buffer layer 120.

The gate insulating layer 140 may be formed by an atomic layer deposition (ALD) method or a metal organic chemical vapor deposition (MOCVD). The gate insulating layer 140 may or may not be patterned. FIG. 1 illustrates a structure in which the gate insulating layer 140 is not patterned.

The gate electrodes 150 and 250 are disposed on the gate insulating layer 140. The gate electrodes 150 and 250 may include a first gate electrode 150 and a second gate electrode 250. Referring to FIGS. 1 and 2, the first thin film transistor TR1 includes a first gate electrode 150, and the second thin film transistor TR2 includes a second gate electrode 250. The gate electrodes 150 and 250 are spaced apart from the active layers 130 and 230 to at least partially overlap the active layers 130 and 230.

The gate electrodes 150 and 250 may include at least one of an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, chromium (Cr), tantalum (Ta), neodium (Nd), and titanium (Ti). The gate electrode 150 may have a multilayer structure including at least two conductive layers having different physical properties.

Referring to FIG. 1, the first gate electrode 150 and the second gate electrode 250 may be formed on the same layer. Specifically, the first gate electrode 150 and the second gate electrode 250 may be formed of the same material by the same process.

An interlayer insulating layer 160 is disposed on the gate electrodes 150 and 250. The interlayer insulating layer 160 is disposed on the entire first thin film transistor TR1 and the second thin film transistor TR2. The interlayer insulating layer 160 is an insulating layer made of an insulating material. Specifically, the interlayer insulating layer 160 may be formed of an organic material, an inorganic material, or a laminate of an organic material layer and an inorganic material layer.

Source electrodes 171 and 271 and drain electrodes 172 and 272 are disposed on the interlayer insulating layer 160. The source electrodes 171 and 271 and the drain electrodes 172 and 272 are spaced apart from each other and are connected to the active layers 130 and 230, respectively. The source electrodes 171 and 271 and the drain electrodes 172 and 272 are connected to the active layers 130 and 230 through contact holes formed in the interlayer insulating layer 160, respectively.

Each of the source electrodes 171 and 271 and the drain electrodes 172 and 272 may include at least one of molybdenum (Mo), aluminum (Al), chromium (Cr), gold (Au), titanium (Ti), nickel (Ni), neodium (Nd), copper (Cu), and alloys thereof. Each of the source electrodes 171 and 271 and the drain electrodes 172 and 272 may be formed of a single layer formed of a metal or an alloy of metals, or may be formed of a multilayer of two or more layers.

According to an embodiment of the present disclosure, the active layers 130 and 230 may be selectively conductorized by selectively conducting the active layers 130 and 230. Applying conductivity to specific portions of the active layers 130 and 230 is referred to as selectively conducting the active layers 130 and 230. The selectively conductorized portion may have a higher carrier concentration than the portion that is not.

According to one embodiment of the present disclosure, the active layers 130 and 230 can be selectively conductorized by using the gate electrodes 150 and 250 as masks. In this case, the regions of the active layers 130 and 230 that overlap the gate electrodes 150 and 250 are not conductorized and become channel portions 130n and 230n. Areas of the active layers 130 and 230 that do not overlap the gate electrodes 150 and 250 are conductorized and become first connection parts 130a and 230a and second connection parts 130b and 230b. The first connection parts 130a and 230a and the second connection parts 130b and 230b may generally be formed on both sides of the channel parts 130n and 230n.

According to an embodiment of the present disclosure, the active layers 130 and 230 may be selectively conductorized by doping, plasma treatment, or dry etching.

For example, the active layers 130 and 230 may be selectively conductorized by doping using a dopant. For doping in the selective conductorization process, for example, at least one dopant selected from boron (B) ions, phosphorus (P) ions, arsenic (As) ions, and antimony (Sb) ions may be used. In this case, the doped region can be conductorized.

One of the first connection parts 130a and 230a and the second connection parts 130b and 230b becomes a source region, and the other thereof becomes a drain region. Referring to FIG. 1, first connection parts 130a and 230a may be source regions connected to source electrodes 171 and 271. The second connection parts 130b and 230b may be drain regions connected to drain electrodes 172 and 272. In an embodiment of the present disclosure, the source region and the drain region are only referred to for convenience of description, and the source region and the drain region may be switched.

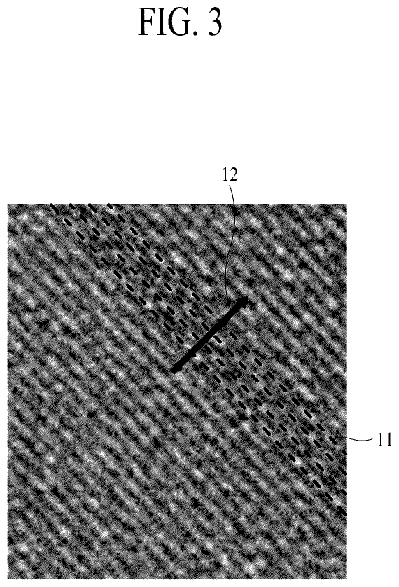

FIG. 3 is a photograph of an oxide semiconductor layer having a crystalline structure according to another embodiment of the present disclosure.

Specifically, FIG. 3 is a transmission electron microscope (TEM) photograph of the second oxide semiconductor layers 132 and 232 of the first active layer 130 and the second active layer 230 having a crystalline structure, and is a diagram showing the crystal surfaces 11 and the crystal direction 12 of the second oxide semiconductor layers 132 and 232.

In particular, referring to FIG. 3, it may be seen that the crystals of the second oxide semiconductor layers 132 and 232 including the IGO (InGaO)-based oxide semiconductor material were uniformly grown in the (222) direction (diagonal direction). In this case, the crystal direction 12 of the crystal plane 11 shown in FIG. 3 corresponds to the (222) direction.

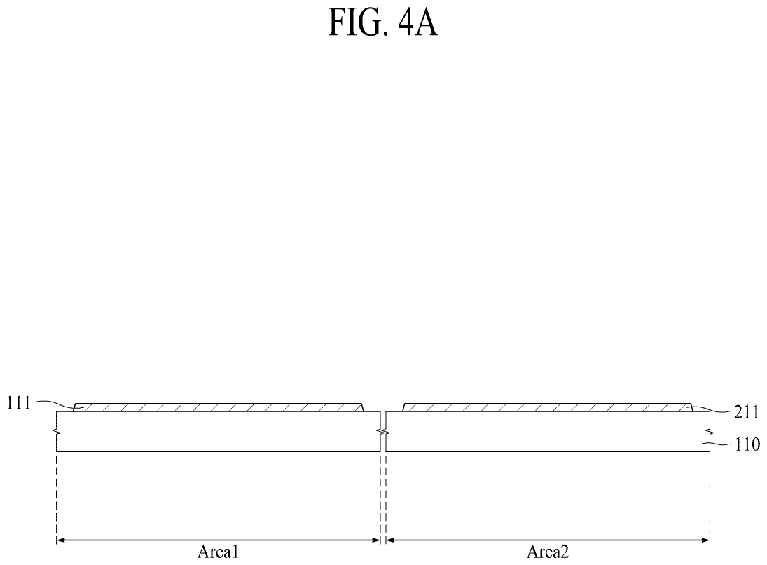

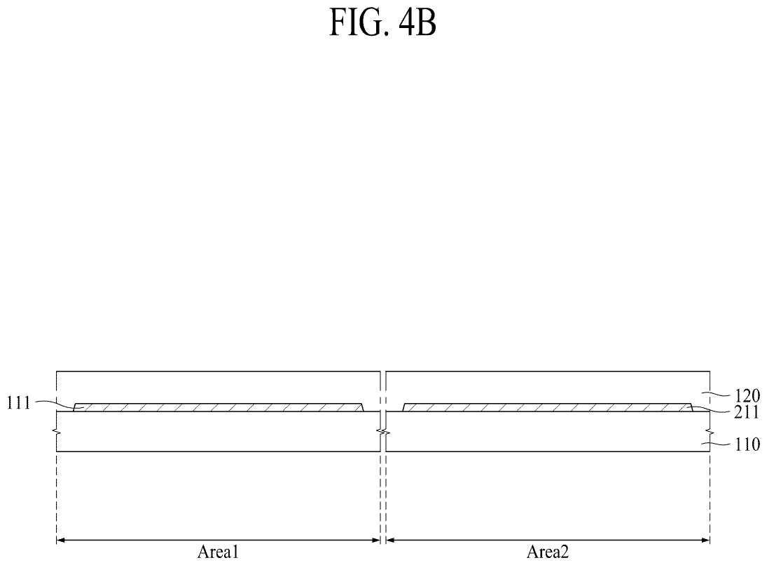

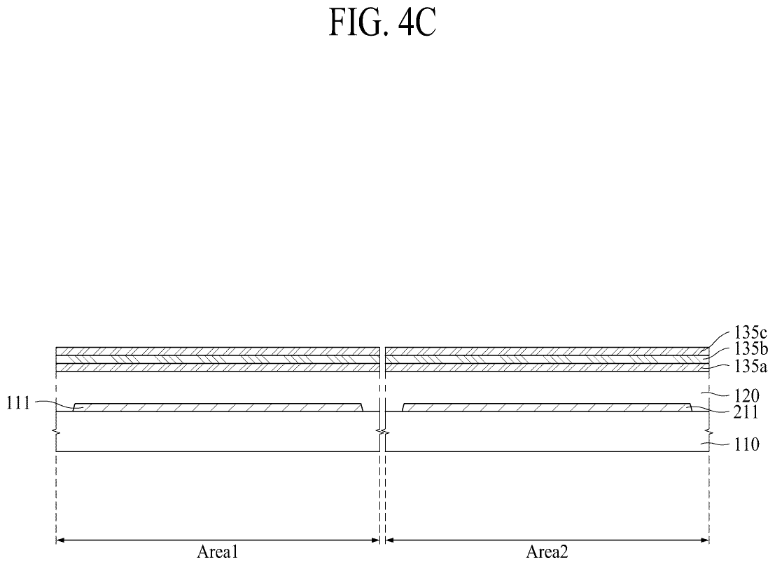

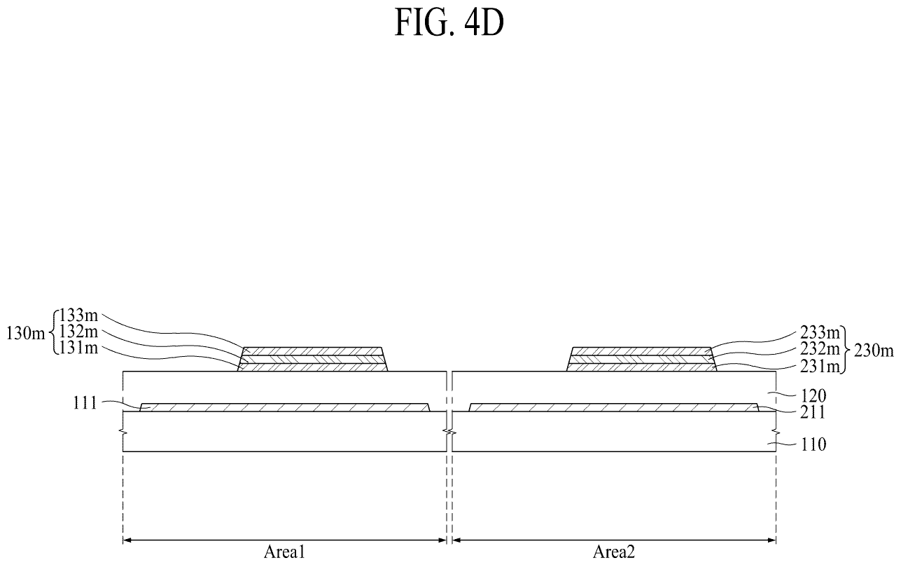

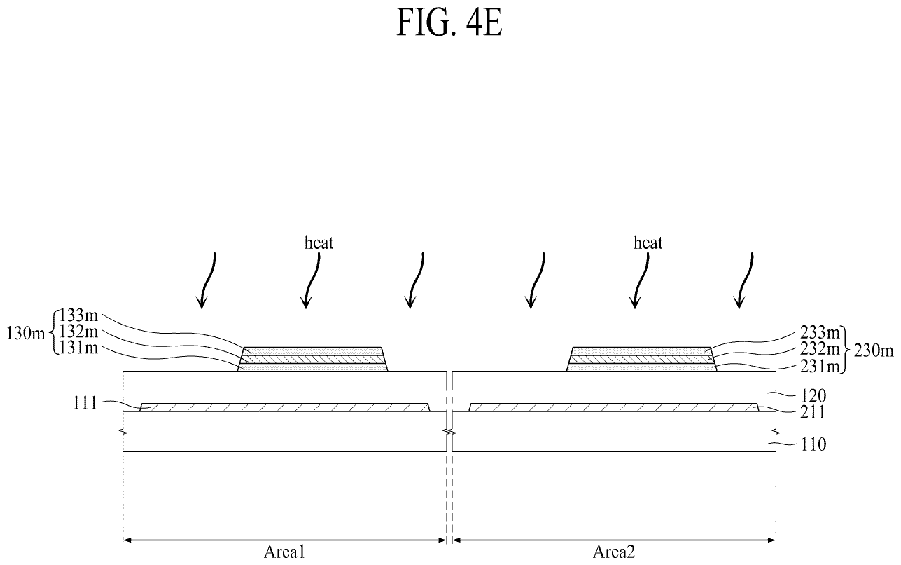

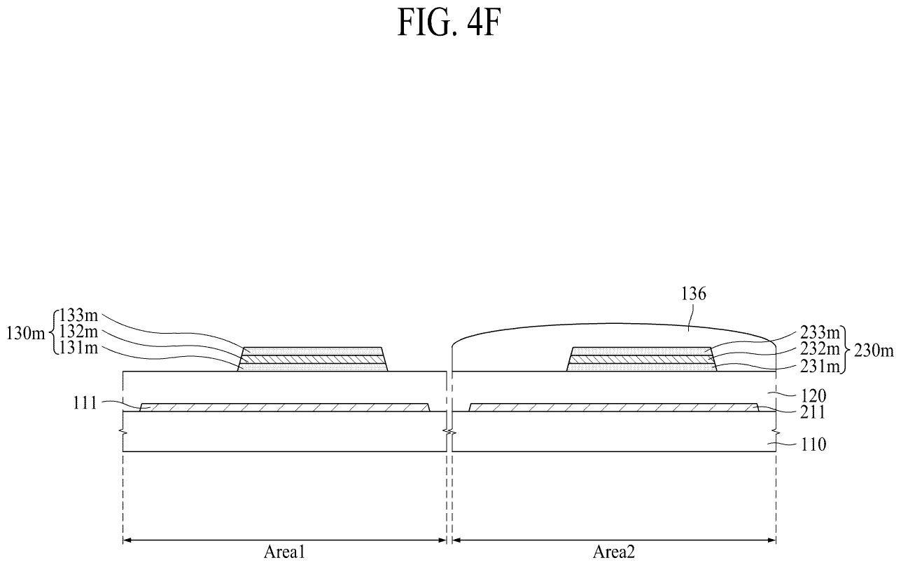

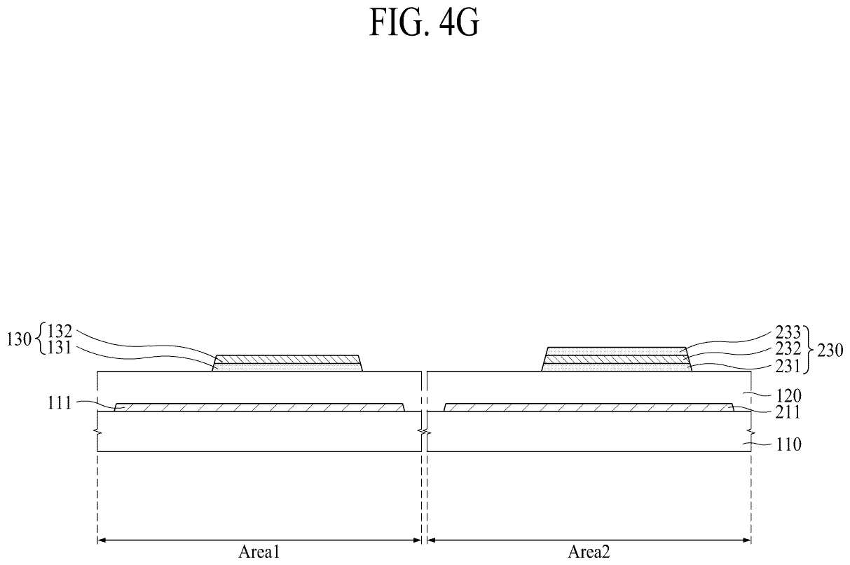

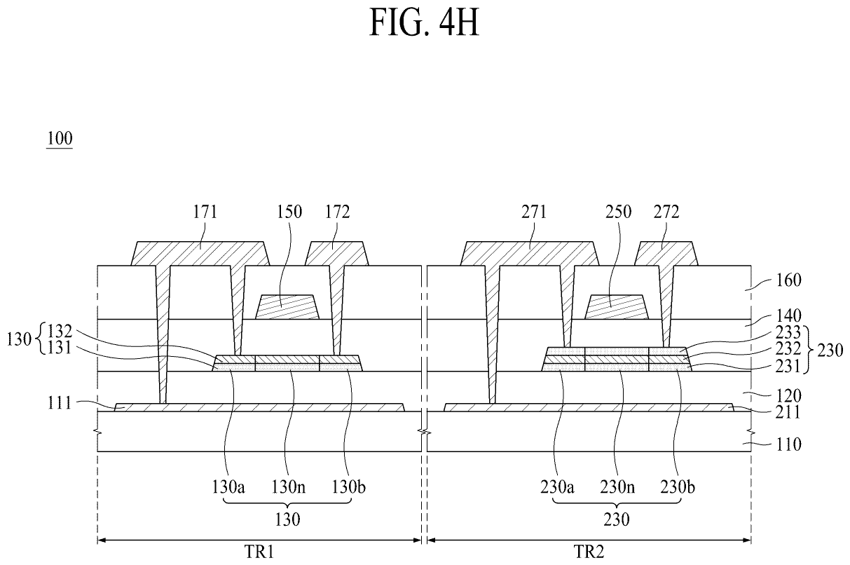

FIGS. 4A to 4H are manufacturing process diagrams of a thin film transistor substrate 100 according to another embodiment of the present disclosure. A description of the components described above is omitted.

Referring to FIG. 4A, light blocking layers 111 and 211 are formed on the base substrate 110. Specifically, after the base substrate 110 disposed in the first area Area1 and the second area Area2 is prepared, a first light blocking layer 111 may be formed on the base substrate 110 disposed in the first area Area1, and a second light blocking layer 211 may be formed on the base substrate 110 disposed in the second area Area2.

Referring to FIG. 4B, a buffer layer 120 is formed on the light blocking layers 111 and 211. In detail, a buffer layer 120 may be integrally formed on the first light blocking layer 111 disposed in the first area Area1 and the second light blocking layer 211 disposed in the second area Area2.

Referring to FIG. 4C, a first oxide semiconductor material layer 135a, a second oxide semiconductor material layer 135b, and a third oxide semiconductor material layer 135c may be sequentially stacked on the base substrate 110. In this case, the first oxide semiconductor material layer 135a, the second oxide semiconductor material layer 135b, and the third oxide semiconductor material layer 135c may be formed over the entire first area Area1 and the second area Area2.

In this case, each of the first oxide semiconductor material layer 135a and the third oxide semiconductor material layer 135c may include at least one of an IZO-based (InZnO)-based, an IGZO (InGaZnO)-based, an IGZTO (InGaZnSnO)-based, a GZTO (GaZnSnO)-based, and a GZO (GaZnO)-based oxide semiconductor material, and the second oxide semiconductor material layer 135b may include at least one of an InZnO (InZnO)-based, an IGO (InGaO)-based, an IGZO (InGaZnO)-based, an ITO (InSnO)-based, an IGZTO (InGaZnSnO)-based, and an ITZO (InSnZnO)-based oxide semiconductor material.

Specifically, the second oxide semiconductor material layer 135b may include at least one of an IZO (InZnO)-based oxide semiconductor material, in which the concentration of In is 50% or more compared to the total concentration of In and Zn, an IGO (InGaO)-based oxide semiconductor material, in which the concentration of In is 70% or more compared to the total concentration of In and Ga, an IGZO (InGaZnO)-based oxide semiconductor material, in which the concentration of In is 50% or more compared to the total concentration of In, Ga, and Zn, an ITO (InSnO)-based oxide semiconductor material, in which the concentration of In is 80% or more compared to the total concentration of In and Sn, an IGZTO (InGaZnSnO)-based oxide semiconductor material, in which the sum of concentration of In and Sn is 45% or more compared to the total concentration of In, Ga, Zn, and Sn, and an ITZO (InSnZnO)-based oxide semiconductor material, in which the sum of concentration of In and Sn is 45% or more compared to the total concentration of In, Sn, Zn based on atomic number.

In this case, the first oxide semiconductor material layer 135a, the second oxide semiconductor material layer 135b, and the third oxide semiconductor material layer 135c may be formed by sputtering deposition. When the first oxide semiconductor material layer 135a and the third oxide semiconductor material layer 135c are formed, sputtering deposition may be performed at a temperature of 15° C. to less than 100° C. In some embodiments, it may be performed at a temperature of 15° C. to 70° C. In some embodiments, it may be performed at a temperature of 15° C. to 50° C.

When forming the second oxide semiconductor material layer 135b, sputter deposition may be performed at a temperature of 100 to 300° C. When the second oxide semiconductor material layer 135b is deposited at a temperature of 100 to 300° C., the second oxide semiconductor material layer 135b may increase film density compared to room temperature deposition and have few defects in the film, thereby forming a film that is easy to crystallize. Specifically, during high-temperature film formation, the amorphous state is the same, but stoichiometry is improved and there are few defects inside the film, so that crystallization may occur better in heat treatment for crystallization. Even in this case, the second oxide semiconductor material layer 135b has an amorphous structure.

When the second oxide semiconductor material layer 135b is formed under a high-temperature sputtering condition, the second oxide semiconductor material layer 135b may partially form an arrangement. In this case, even if it undergoes a conductorization process after crystallization, it is possible to prevent the problem of returning to the amorphous structure.

In addition, when the second oxide semiconductor material layer 135b is formed by a high-temperature sputtering condition, the second oxide semiconductor material layer 135b may have a higher film density after the crystallization step compared to a case where the high-temperature sputtering step is not performed. Therefore, there is an advantage that it does not return to the amorphous structure even if it goes through a conductorization process after crystallization.

Referring to FIG. 4D, the first oxide semiconductor material layer 135a, the second oxide semiconductor material layer 135b, and the third oxide semiconductor material layer 135c may be patterned to form the first active pattern 130m and the second active pattern 230m including the first oxide semiconductor pattern layers 131m and 231m, the second oxide semiconductor pattern layers 132m and 232m, and the third oxide semiconductor pattern layers 133m and 233m, respectively.

In this case, the first active pattern 130m is disposed on the buffer layer 120 of the first area Area1, and the second active pattern 230m is disposed on the buffer layer 120 of the second area Area2.

In addition, referring to FIG. 4D, the first active pattern 130m may include a first oxide semiconductor pattern layer 131m, a second oxide semiconductor pattern layer 132m, and a third oxide semiconductor pattern layer 133m, and the second active pattern 230m may include a first oxide semiconductor pattern layer 231m, a second oxide semiconductor pattern layer 232m, and a third oxide semiconductor pattern layer 233m, which are sequentially stacked.

Referring to FIG. 4E, the first active pattern 130m and the second active pattern 230m may be heat-treated. In this case, the step of heat-treating the first active pattern 130m and the second active pattern 230m may be performed at a temperature of 350 to 450° C.

Referring to FIGS. 4E and 4F, the second oxide semiconductor pattern layers 132m and 232m have a crystallization structure by the heat treatment step, and the first oxide semiconductor pattern layers 131m and 231m and the third oxide semiconductor pattern layers 133m and 233m have amorphous structures, respectively.

Furthermore, by the sputter deposition step and the heat treatment step described above, the second oxide semiconductor pattern layers 132m and 232m may be crystallized first, and the crystallized second oxide semiconductor pattern layers 132m and 232m may serve as a catalyst for an amorphous oxide semiconductor layer stacked on the upper and lower portions of the second oxide semiconductor pattern layers 132m and 232m to form a crystallized oxide semiconductor layer. The crystallized oxide semiconductor layer may correspond to the third oxide semiconductor layer 133, the fourth oxide semiconductor layers 134 and 234 and the fifth oxide semiconductor layer 235 described above.

In other words, the crystallized second oxide semiconductor pattern layers 132m and 232m may serve as a catalyst for the amorphous oxide semiconductor layers stacked on the upper and lower portions of the second oxide semiconductor pattern layers 132m and 232m, and the amorphous oxide semiconductor layers stacked on the upper and lower portions of the second oxide semiconductor pattern layers 132m and 232m may be eroded in the direction of the second oxide semiconductor pattern layers 132m and 232m to form a crystallized oxide semiconductor layer.

Referring to FIG. 4F, a photoresist material layer 136 may be formed to overlap the second active pattern 230m disposed in the second area Area2. Specifically, the photoresist material layer 136 does not overlap the first active pattern 130m disposed in the first area Area1.

Referring to FIG. 4G, the third oxide semiconductor pattern layer 133m of the first active pattern 130m may be wet-etched using the photoresist material layer 136 as a mask. The first active layer 130 and the second active layer 230 are formed by such wet-etching.

The first active layer 130 includes a first oxide semiconductor layer 131 and a second oxide semiconductor layer 132, and the second active layer 230 includes a first oxide semiconductor layer 231, a second oxide semiconductor layer 232, and a third oxide semiconductor layer 233.

Although not illustrated in the drawing, the first active layer 130 may further include a third oxide semiconductor layer 133 disposed between the first oxide semiconductor layer 131 and the second oxide semiconductor layer 132, and a fourth oxide semiconductor layer 134 disposed on the second oxide semiconductor layer 132.

In addition, the second active layer 230 may further include a fourth oxide semiconductor layer 234 disposed between the first oxide semiconductor layer 231 and the second oxide semiconductor layer 232, and a fifth oxide semiconductor layer 235 disposed between the second oxide semiconductor layer 232 and the third oxide semiconductor layer 233.

Referring to FIG. 4H, gate insulating layers 140, gate electrodes 150 and 250, interlayer insulating layers 160, source electrodes 171 and 271, and drain electrodes 172 and 272 may be sequentially formed on the first active layer 130 and the second active layer 230.

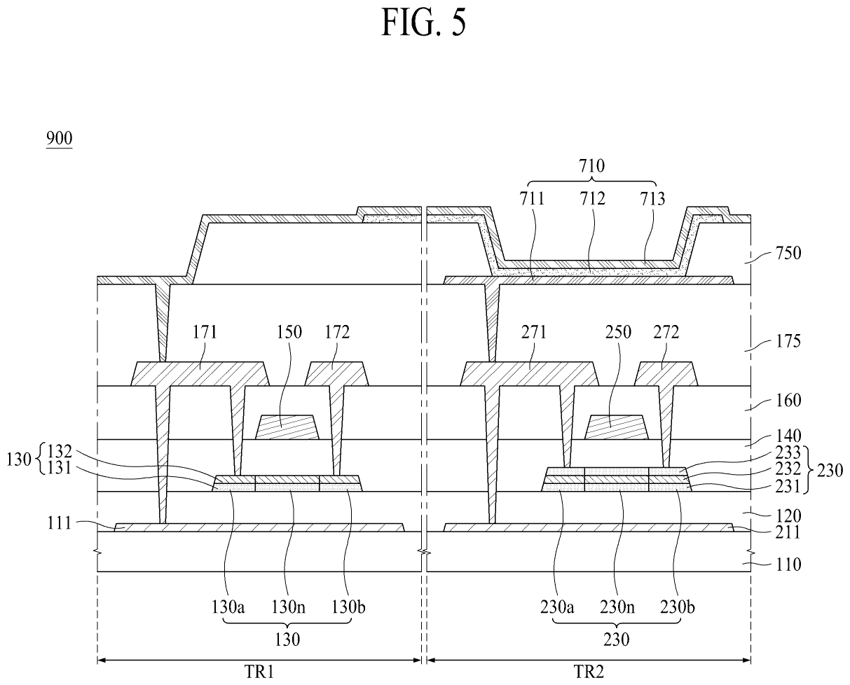

FIG. 5 is a partial cross-sectional view of a display apparatus 900 according to another embodiment of the present disclosure.

The display apparatus 900 according to another embodiment of the present disclosure may include the thin film transistor substrates 100 and 200 and the display device 710 described above. Although a case where the thin film transistor substrate 100 according to FIG. 1 is used is illustrated in FIG. 5, an embodiment of the present disclosure is not limited thereto. Any one of the thin film transistor substrates 200 shown in FIG. 2 may be used as a thin film transistor substrate of the display apparatus 900 according to another embodiment of the present disclosure.

Referring to FIG. 5, the display device 710 may include a first electrode 711, an organic light emitting layer 712 on the first electrode 711, and a second electrode 713 on the organic light emitting layer 713. The display apparatus 900 of FIG. 5 is an organic light emitting display apparatus including an organic light emitting diode (OLED) as the display device 710.

Referring to FIG. 5, the planarization layer 175 may be disposed on the first thin film transistor TR1 and the second thin film transistor TR2, and the first electrode 711 of the display device 710 may be disposed on the planarization layer 175. Here, the planarization layer 175 planarizes the upper portions of the first thin film transistor TR1 and the second thin film transistor TR2 and protects the first thin film transistor TR1 and the second thin film transistor TR2.

A bank layer 750 is disposed on an edge of the first electrode 711. The bank layer 750 defines a light emitting area of the display device 710. An organic light emitting layer 712 is disposed on the first electrode 711 and a second electrode 713 is disposed on the organic light emitting layer 712 to form an organic light emitting diode (OLED) in the display device 710.

In the display apparatus 900 of FIG. 5, the first thin film transistor TR1 may be a transistor of a gate driver. Also, the first thin film transistor TR1 of FIG. 5 may serve as a switching transistor of the display panel.

The second thin film transistor TR2 of FIG. 5 is connected to the display device 710 and may serve as a driving transistor for driving the display device 710.

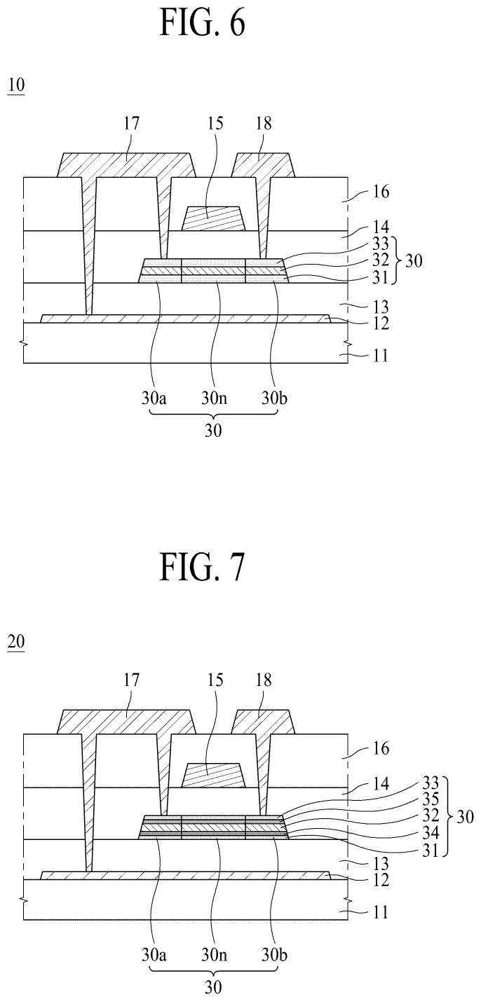

FIG. 6 is a cross-sectional view of a thin film transistor 10 according to an embodiment of the present disclosure. FIG. 7 is a cross-sectional view of a thin film transistor 20 according to another embodiment of the present disclosure.

Referring to FIGS. 6 and 7, the thin film transistors 10 and 20 include an active layer 30 and a gate electrode 15 spaced apart from the active layer 30 and overlapping at least partially with the active layer 30.

The thin film transistors 10 and 20 according to an embodiment of the present disclosure further include a base substrate 11.

Glass or plastic may be used as the base substrate 11. Transparent plastic having a flexible characteristic, for example, polyimide, may be used as the plastic. The base substrate 11 illustrated in FIGS. 6 and 7 may correspond to the base substrate 110 illustrated in FIGS. 1 and 2.

A light blocking layer 12 may be disposed on the base substrate 11. The light blocking layer 12 blocks light incident from the base substrate 11 to protect the active layer 30. When another structure acts as a light blocking, the light blocking layer 12 may be omitted. The light blocking layer 12 illustrated in FIGS. 6 and 7 may correspond to the light blocking layers 111 and 211 illustrated in FIGS. 1 and 2.

According to an embodiment of the present disclosure, a buffer layer 13 may be disposed on the base substrate 11 and the light blocking layer 12.

The buffer layer 13 has insulating properties and protects the active layer 30. The buffer layer 13 may include at least one of silicon oxide (SiOx), silicon nitride (SiNx), and metal oxide having insulating properties. The base substrate 11 illustrated in FIGS. 6 and 7 may correspond to the base substrate 110 illustrated in FIGS. 1 and 2.

The active layer 30 may be disposed on the buffer layer 13.

The active layer 30 includes an oxide semiconductor material. According to an embodiment of the present disclosure, the active layer 30 is an oxide semiconductor layer made of an oxide semiconductor material. The active layer 30 made of an oxide semiconductor material includes metal and oxygen (O).

In addition, the active layer 30 may include at least one layer having a crystalline structure.

According to an embodiment of the present disclosure, the active layer 30 includes a first oxide semiconductor layer 31, a second oxide semiconductor layer 32, and a third oxide semiconductor layer 33. The second oxide semiconductor layer 32 is disposed on the first oxide semiconductor layer 31, and the third oxide semiconductor layer 33 is disposed on the second oxide semiconductor layer 32.

According to an embodiment of the present disclosure, the first oxide semiconductor layer 31 and the third oxide semiconductor layer 33 of the active layer 30 may have an amorphous structure, and the second oxide semiconductor layer 32 may have a crystalline structure. According to an embodiment of the present disclosure, the crystalline structure and the amorphous structure are referred to based on the content of crystal grains contained in the oxide semiconductor layer. More specifically, according to an embodiment of the present disclosure, the crystalline structure and the amorphous structure are referred to based on the ratio of the grains having a particle diameter of 1 nm or more.

The contents of the crystalline structure and the amorphous structure are already described above and are omitted.

According to an embodiment of the present disclosure, the first oxide semiconductor layer 31 and the third oxide semiconductor layer 33 have an amorphous structure. Specifically, in the cross-sectional images of the first oxide semiconductor layer 31 and the third oxide semiconductor layer 33 photographed by the transmission electron microscope (TEM), the ratio of crystal grain having a particle diameter of 1 nm or more may be 10% or less of the total cross-sectional area. More specifically, in the cross-sectional images of the first oxide semiconductor layers 31 and the third oxide semiconductor layer 33 photographed by the transmission electron microscope (TEM), the ratio of the grains having a particle diameter of 5 nm to 10 nm may be 10% or less of the total cross-sectional area.

The first oxide semiconductor layer 31 and the third oxide semiconductor layer 33 of the active layer 30 may include at least one of an IZO (InZnO)-based, an IGZO (InGaZnO)-based, an IGZTO (InGaZnSnO)-based, a GZTO (GaZnSnO)-based, and a GZO (GaZnSnO)-based oxide semiconductor material. More specifically, the first oxide semiconductor layer 31 and the third oxide semiconductor layer 33 of the active layer 30 may include an IGZO (InGaZnO)-based oxide semiconductor material. In some embodiments, the first oxide semiconductor layer 31 and the third oxide semiconductor layer 33 may include an IGZO (InGaZnO)-based oxide semiconductor material.

According to an embodiment of the present disclosure, the first oxide semiconductor layer 31 of the active layer 30 may have a thickness of 1 to 10 nm, the second oxide semiconductor layer 32 may have a thickness of 10 to 50 nm, and the third oxide semiconductor layer 33 may have a thickness of 1 to 20 nm.

According to an embodiment of the present disclosure, the second oxide semiconductor layer 32 may have a crystalline structure by adjusting the composition and manufacturing conditions during the manufacturing process of the second oxide semiconductor layer 32. For example, in order to form a crystalline structure, the second oxide semiconductor layer 32 may be formed by sputtering deposition and heat treatment performed at a temperature of 350 to 450° C. In this case, sputtering deposition may be performed at a temperature of 100 to 300° C.

According to an embodiment of the present disclosure, the second oxide semiconductor layer 32 has a crystalline structure. Specifically, in the cross-sectional image of the second oxide semiconductor layer 32 photographed by a transmission electron microscope (TEM), the ratio of crystal grains having a particle diameter of 1 nm or more may be 50% or more of the total cross-sectional area. More specifically, in the cross-sectional image of the second oxide semiconductor layer 32 photographed by a transmission electron microscope (TEM), the ratio of crystal grain having a particle diameter of 5 nm to 10 nm may be 50% or more of the total cross-sectional area.

The second oxide semiconductor layer 32 may include at least one of an IZO (InZnO)-based oxide semiconductor material, in which the concentration of In is 50% or more compared to the total concentration of In and Zn, an IGO (InGaO)-based oxide semiconductor material, in which the concentration of In is 70% or more compared to the total concentration of In and Ga, an IGZO (InGaZnO)-based oxide semiconductor material, in which the concentration of In is 50% or more compared to the total concentration of In, Ga, and Zn, an ITO (InSnO)-based oxide semiconductor material, in which the concentration of In is 80% or more compared to the total concentration of In and Sn, an IGZTO (InGaZnSnO)-based oxide semiconductor material, in which the sum of concentration of In and Sn is 45% or more compared to the total concentration of In, Ga, Zn, and Sn, and an ITZO (InSnZnO)-based oxide semiconductor material, in which the sum of concentration of In and Sn is 45% or more compared to the total concentration of In, Sn, Zn based on atomic number. In some embodiments, the second oxide semiconductor layers 32 may include an IZO (InZnO)-based oxide semiconductor material, in which the concentration of In is 50% or more compared to the total concentration of In and Zn.

According to an embodiment of the present disclosure, the second oxide semiconductor layer 32 may be doped with a dopant. For example, the dopant may be doped into the second oxide semiconductor layer 32 by an ion implantation method. Accordingly, according to an embodiment of the present disclosure, the second oxide semiconductor layer 32 may further include a dopant doped into an oxide semiconductor material. The dopant may include at least one of beryllium (Be), boron (B), carbon (C), aluminum (Al), silicon (Si), iron (Fe), calcium (Ca), tin (Sn), titanium (Ti), tantalum (Ta), vanadium (V), yttrium (Y), zirconium (Zr), hafnium (Hf), lanthanum (La), and germanium (Ge). Specifically, the second oxide semiconductor layers 32 may be formed of an IGO (InGaO)-based oxide semiconductor material doped with at least one of beryllium (Be), boron (B), carbon (C), aluminum (Al), silicon (Si), iron (Fc), calcium (Ca), tin (Sn), titanium (Ti), tantalum (Ta), vanadium (V), yttrium (Y), zirconium (Zr), hafnium (Hf), lanthanum (La), and germanium (Ge).

The dopant included in the second oxide semiconductor layer 32 may have a content of 0.1 to 10 atomic % based on the total number of atoms in the second oxide semiconductor layer 32. Specifically, the dopant included in the second oxide semiconductor layer 32 may have a content of 0.1 to 10 atomic % based on the total number of atoms in the second oxide semiconductor layer 32, and the dopant included in the second oxide semiconductor layer 32 may have a content of 0.1 to 10 atomic % based on the total number of atoms in the second oxide semiconductor layer 32.

When the dopant is doped into the second oxide semiconductor layer 32, defects in particles of the second oxide semiconductor layer 32 may be prevented so that the second oxide semiconductor layer 32 may have a stable crystal structure, and crystal grains having a particle diameter of 3 to 500 nm may be easily formed in the second oxide semiconductor layer 32.

According to an embodiment of the present disclosure, the second oxide semiconductor layer 32 may have at least one of a (400) crystal plane, a (222) crystal plane, a (220) crystal plane, a (311) crystal plane, and a (0016) crystal plane.

According to an embodiment of the present disclosure, the second oxide semiconductor layer 32 may have at least one of a Cubic crystal structure, a Bixbyite crystal structure, a spinel crystal structure, and a hexagonal crystal structure.

According to an embodiment of the present disclosure, the thin film transistor 10 may include an active layer 30 having a triple layer structure (amorphous-crystalline-amorphous). When the active layer 30 of the thin film transistor 10 has a triple layer structure (amorphous-crystalline-amorphous), the second oxide semiconductor layer 32 having the crystalline structure and the third oxide semiconductor layer 33 having the amorphous structure may serve as a channel layer.

In the case of the thin film transistor 10, in which both the second oxide semiconductor layer 32 having the crystalline structure and the third oxide semiconductor layer 33 having the amorphous structure serve as the channel layer, the second oxide semiconductor layer 32 having the crystalline structure may serve as the main channel layer. In this case, the third oxide semiconductor layer 33 having the amorphous structure is disposed between the second oxide semiconductor layer 32 serving as the main channel layer and the gate insulating layer 14, and a smaller amount of electrons is trapped between the active layer 30 and the gate insulating layer 14. More specifically, a smaller amount of electrons may be trapped at the interface between the active layer 30 and the gate insulating layer 14. As a result, the thin film transistor 10 may have high reliability. More specifically, the thin film transistor 10 may have a high s-factor.

The first oxide semiconductor layer 31, the second oxide semiconductor layer 32, and the third oxide semiconductor layer 33 of the active layer 30 illustrated in FIGS. 6 and 7 correspond to the first oxide semiconductor layer 231, the second oxide semiconductor layer 232, and the third oxide semiconductor layer 233 of the second active layer 230 illustrated in FIGS. 1 and 2, and repeated descriptions are omitted.

According to an embodiment of the present disclosure, the active layer 30 of the thin film transistor 20 may further include a fourth oxide semiconductor layer 34 and a fifth oxide semiconductor layer 35.

The fourth oxide semiconductor layer 34 of the active layer 30 is disposed between the first oxide semiconductor layer 31 and the second oxide semiconductor layer 32 of the active layer 30, and the fifth oxide semiconductor layer 35 of the active layer 30 is disposed between the second oxide semiconductor layer 32 and the third oxide semiconductor layer 33 of the active layer 30.

In this case, the fourth oxide semiconductor layer 34 and the fifth oxide semiconductor layer 35 of the active layer 30 have a crystalline structure.

By adjusting the manufacturing conditions during the manufacturing process of the fourth oxide semiconductor layer 34 and the fifth oxide semiconductor layer 35, the fourth oxide semiconductor layer 34 and the fifth oxide semiconductor layer 35 may have a crystalline structure. For example, in order to form a crystalline structure, a step of heat treatment during formation of the active layer 30 may be included. In this case, the heat treatment may be performed at a temperature of 350 to 450° C.

The fourth oxide semiconductor layer 34 and the fifth oxide semiconductor layer 35 may include at least one of an IZO (InZnO)-based, an IGZO (InGaZnO)-based, an IGZTO (InGaZnSnO)-based, a GZTO (GaZnSnO)-based, and a GZO (GaZnSnO)-based oxide semiconductor material.

According to an embodiment of the present disclosure, the fourth oxide semiconductor layer 34 of the active layer 30 may be made of the same material as the first oxide semiconductor layer 31 of the active layer 30, and the fifth oxide semiconductor layer 35 of the active layer 30 may be made of the same material as the third oxide semiconductor layer 33 of the active layer 30.

When the active layer 30 is formed, the second oxide semiconductor layer 32 is crystallized first, and the crystallized second oxide semiconductor layer 32 serves as a catalyst for the amorphous oxide semiconductor layer stacked on the upper and lower parts of the second oxide semiconductor layer 32 to form the crystallized fourth oxide semiconductor layer 34 and the fifth oxide semiconductor layer 35.

In other words, the crystallized second oxide semiconductor layer 32 serves as a catalyst for the amorphous oxide semiconductor layer stacked on the upper and lower parts of the second oxide semiconductor layer 32, and the amorphous oxide semiconductor layer stacked on the upper and lower parts of the second oxide semiconductor layer 32 erodes in the direction of the second oxide semiconductor layer 32 to form the fourth oxide semiconductor layer 34 and the fifth oxide semiconductor layer 35.

Accordingly, the fourth oxide semiconductor layer 34 and the fifth oxide semiconductor layer 35 are crystallized layers by eroding an amorphous structure having high reliability. That is, even if the fourth oxide semiconductor layer 34 and the fifth oxide semiconductor layer 35 have a crystallized structure, mobility may be slightly lower than that of the second oxide semiconductor layer 32, and reliability may be high.

When the active layer 30 of the thin film transistor 20 has a five-layer structure (amorphous-crystalline-crystalline-crystalline-amorphous), the second oxide semiconductor layer 32, the fourth oxide semiconductor layer 34, the fifth oxide semiconductor layer 35 having a crystalline structure, and the third oxide semiconductor layer 33 having an amorphous structure may serve as a channel layer.

In this case, in the case of the thin film transistor 20, in which the second oxide semiconductor layer 32, the fourth oxide semiconductor layer 34, the fifth oxide semiconductor layer 35 having a crystalline structure, and the third oxide semiconductor layer 33 having the amorphous structure all serve as channel layers, the second oxide semiconductor layer 32, the fourth oxide semiconductor layer 34, and the fifth oxide semiconductor layer 35 having the crystalline structure serve as main channel layers, and the third oxide semiconductor layer 33 having the amorphous structure is disposed between the fifth oxide semiconductor layer 35 and the gate insulating layer 14 disposed at the top end of the main channel layer, and a smaller amount of electrons is trapped between the active layer 30 and the gate insulating layer 14. As a result, the thin film transistor 20 may have high reliability. More specifically, the thin film transistor 20 may have a high s-factor.

According to an embodiment of the present disclosure, the active layer 30 includes the fifth oxide semiconductor layer 35 having both reliability and mobility between the second oxide semiconductor layer 32 having high mobility and the third oxide semiconductor layer 33 having high reliability, so that the thin film transistor 20 may simultaneously secure mobility and reliability.

In the cross-sectional images of the fourth oxide semiconductor layer 34 and the fifth oxide semiconductor layer 35 of the active layer 30, the ratio of crystal grains having a particle diameter of 1 nm or more may be 50% or more of the total cross-sectional area. More specifically, in the cross-sectional images of the fourth oxide semiconductor layer 34 and the fifth oxide semiconductor layer 35 photographed by the transmission electron microscope TEM, the ratio of grain having a particle diameter of 5 nm to 10 nm may be 50% or more of the total cross-sectional area.

According to an embodiment of the present disclosure, the fourth oxide semiconductor layer 34 and the fifth oxide semiconductor layer 35 of the active layer 30 may have (009) crystal planes. Specifically, the fourth oxide semiconductor layer 34 and the fifth oxide semiconductor layer 35 of the active layer 30 may have CAAC crystal structures.

More specifically, the fourth oxide semiconductor layer 34 and the fifth oxide semiconductor layer 35 of the active layer 30 may have different crystal surfaces and crystal structures from those of the second oxide semiconductor layer 32.

According to an embodiment of the present disclosure, the fourth oxide semiconductor layer 34 and the fifth oxide semiconductor layer 35 of the active layer 30 may include crystal grains having a particle diameter of 1 to 10 nm. Specifically, the fourth oxide semiconductor layer 34 and the fifth oxide semiconductor layer 35 of the active layer 30 may have grains smaller than those of the second oxide semiconductor layer 32.

Small crystal grains included in the fourth oxide semiconductor layer 34 and the fifth oxide semiconductor layer 35 of the active layer 30 may be easily etched compared to huge crystals.

The fourth oxide semiconductor layer 34 and the fifth oxide semiconductor layer 35 of the active layer 30 made of small crystal grains have excellent etching characteristics, and thus may be easily patterned.

According to an embodiment of the present disclosure, the fourth oxide semiconductor layer 34 and the fifth oxide semiconductor layer 35 of the active layer 30 may have a thickness of 0.1 to 3 nm.

The first oxide semiconductor layer 31, the second oxide semiconductor layer 32, the third oxide semiconductor layer 33, the fourth oxide semiconductor layer 34, and the fifth oxide semiconductor layer 35 of the active layer 30 shown in FIG. 7 correspond to the first oxide semiconductor layer 231, the second oxide semiconductor layer 232, the third oxide semiconductor layer 233, the fourth oxide semiconductor layer 234, and the fifth oxide semiconductor layer 235 of the second active layer 230 shown in FIG. 2, and repeated descriptions thereof are omitted.

The gate insulating layer 14 is disposed on the active layer 30. The gate insulating layer 14 may include at least one of silicon oxide and silicon nitride, and may include a metal oxide or a metal nitride. The gate insulating layer 14 may have a single layer structure or a multilayer structure. The gate insulating layer 14 may be disposed to cover the entire upper surface of the buffer layer 13. The gate insulating layer 14 illustrated in FIGS. 6 and 7 corresponds to the gate insulating layer 140 illustrated in FIGS. 1 and 2, and repeated descriptions are omitted.

The gate electrode 15 is disposed on the gate insulating layer 14. The gate electrode 15 is spaced apart from the active layer 30 and at least partially overlaps the active layer 30. The gate electrode 15 may include at least one of an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, at least one of chromium (Cr), tantalum (Ta), neodium (Nd), and titanium (Ti). The gate electrode 15 may have a multilayer structure including at least two conductive films having different physical properties.

The gate electrodes 15 illustrated in FIGS. 6 and 7 correspond to the gate electrodes 150 and 250 illustrated in FIGS. 1 and 2, and repeated descriptions thereof are omitted.

An interlayer insulating layer 16 is disposed on the gate electrode 15. The interlayer insulating layer 16 may be formed of an organic material, an inorganic material, or a laminate of an organic material layer and an inorganic material layer.

The interlayer insulating layer 16 illustrated in FIGS. 6 and 7 corresponds to the interlayer insulating layer 160 illustrated in FIGS. 1 and 2, and repeated descriptions thereof are omitted.

The source electrode 17 and the drain electrode 18 are disposed on the interlayer insulating layer 16. The source electrode 17 and the drain electrode 18 are spaced apart from each other and are connected to the active layer 30, respectively. The source electrode 17 and the drain electrode 18 are connected to the active layer 30 through contact holes formed in the interlayer insulating layer 16.

The source electrode 17 and the drain electrode 18 illustrated in FIGS. 6 and 7 correspond to the source electrode 271 and the drain electrode 272 illustrated in FIGS. 1 and 2, and repeated descriptions thereof are omitted.

According to one embodiment of the present disclosure, the active layer 30 can be selectively conductorized by using the gate electrodes 15 as masks. In this case, the regions of the active layer 30 that overlap the gate electrode 15 are not conductorized and become channel portion 30n. Areas of the active layer 30 that do not overlap the gate electrode 15 are conductorized and become first connection part 30a and second connection part 30b. The first connection part 30a and the second connection part 30b may generally be formed on both sides of the channel part 30n.

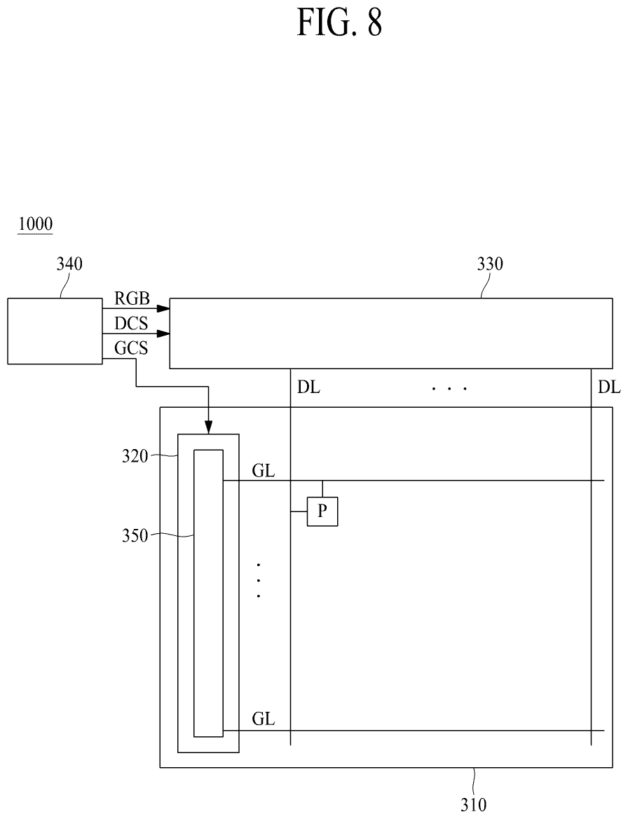

FIG. 8 is a schematic diagram illustrating a display apparatus 1000 according to further still another embodiment of the present disclosure.

As shown in FIG. 8, the display apparatus 1000 according to further still another embodiment of the present disclosure may include a display panel 310, a gate driver 320, a data driver 330 and a controller 340.

The display panel 310 includes gate lines GL and data lines DL, and pixels P are disposed in intersection areas of the gate lines GL and the data lines DL. An image is displayed by driving of the pixels P. The gate lines GL, the data lines DL and the pixels P may be disposed on the base substrate 110.

The controller 340 controls the gate driver 320 and the data driver 330.

The controller 340 outputs a gate control signal GCS for controlling the gate driver 320 and a data control signal DCS for controlling the data driver 330 by using a signal supplied from an external system not shown. Also, the controller 340 samples input image data input from the external system, realigns the sampled data and supplies the realigned digital image data RGB to the data driver 330.

The gate control signal GCS includes a gate start pulse GSP, a gate shift clock GSC, a gate output enable signal GOE, a start signal Vst and a gate clock GCLK. Also, control signals for controlling a shift register may be included in the gate control signal GCS.

The data control signal DCS includes a source start pulse SSP, a source shift clock signal SSC, a source output enable signal SOE and a polarity control signal POL.

The data driver 330 supplies a data voltage to the data lines DL of the display panel 310. In detail, the data driver 330 converts the image data RGB input from the controller 340 into an analog data voltage and supplies the data voltage to the data lines DL.

According to one embodiment of the present disclosure, the gate driver 320 may be packaged on the display panel 310. In this way, a structure in which the gate driver 320 is directly packaged on the display panel 310 will be referred to as a Gate In Panel (GIP) structure. In detail, in the Gate In Panel (GIP) structure, the gate driver 320 may be disposed on the base substrate 110.

The display apparatus 1000 according to one embodiment of the present disclosure may include the above-described thin film transistor substrate 100, and 200. According to one embodiment of the present disclosure, the gate driver 320 may include the first thin film transistor TR1 of the above-described thin film transistor substrate 100, and 200.

The gate driver 320 may include a shift register 350.

The shift register 350 sequentially supplies gate pulses to the gate lines GL for one frame by using the start signal and the gate clock, which are transmitted from the controller 340. In this case, one frame means a time period at which one image is output through the display panel 310. The gate pulse has a turn-on voltage capable of turning on a switching device (thin film transistor) disposed in the pixel P.

Also, the shift register 350 supplies a gate-off signal capable of turning off the switching device, to the gate line GL for the other period of one frame, at which the gate pulse is not supplied. Hereinafter, the gate pulse and the gate-off signal will be collectively referred to as a scan signal SS or Scan.

The shift register 350 may include the first thin film transistor TR1 of the above-described thin film transistor substrate 100, and 200.

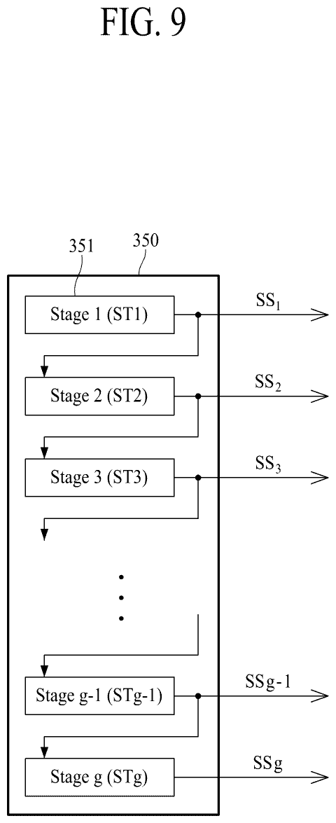

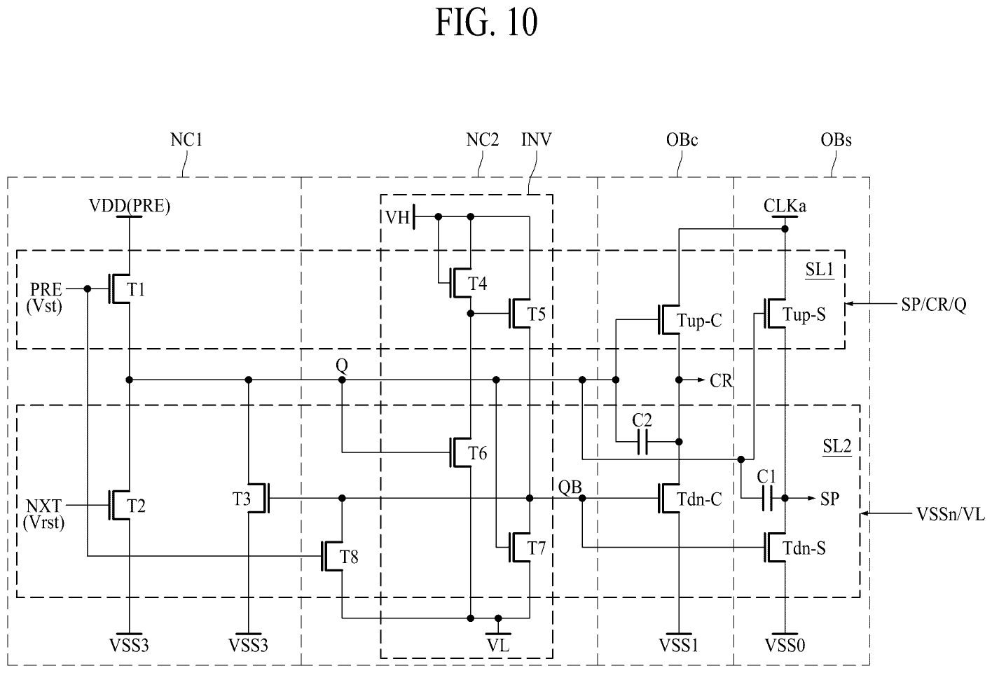

FIG. 9 is a schematic diagram illustrating a shift register 350. FIG. 10 is a circuit diagram of the stage 351 provided in the shift register 350 of FIG. 9.

Referring to FIG. 9, the shift register 350 may include g number of stages 351 (ST1 to STg).

The shift register 350 transmits one scan signal SS to pixels P connected to one gate line GL through one gate line GL. Each of the stages 351 may be connected to one gate line GL. When g number of gate lines GL are formed in the display panel 110, the shift register 350 may include g number of stages 351 (ST1 to STg), and may generate g number of scan signals SS1 to SSg.

In general, each stage 351 outputs the gate pulse GP once during one frame, and the gate pulses GP are sequentially output from each stage 351.

FIG. 10 is a circuit diagram showing a stage 351 of a shift register 350 of the gate driver 320.

One stage 351 of the shift register shown in FIG. 10 includes output units OBc and OBs for supplying an output voltage Vout in response to the logical state of the first node Q, and a first node control unit NC1 for controlling charging and discharging of the first node Q.

The output units OBc and OBs include a pull-up transistor Tup that supplies an output voltage of the clock signal CLKa in response to the control of the first node. The output voltage is supplied to the corresponding gate line as a scan pulse and as a carry signal that controls charging and discharging of other stages.

The first node control unit NC1 includes a first transistor T1 of a set unit for charging the first node Q with the high potential voltage VDD or the front-end output PRE in response to the front-end output PRE from the previous stage, and a second transistor T2 of the reset unit for discharging the first node Q with the low potential voltage VSS, which is a reset voltage, in response to the rear-end output NXT from the next stage. When the stage 351 of FIG. 10 is the first stage ST, a start pulse Vst is supplied instead of the front-end output PRE.

When the stage 351 of FIG. 10 is the last stage, the reset pulse Vrst is supplied instead of the rear-end output NXT.

In the first period, the first node Q is pre-charged by the turned-on first transistor T1 in response to the front-end output PRE or the start pulse Vst, and then floated in a charged state by the first and second transistors T1 and T2 turned off in the second period. In this case, the gate-on voltage (gate high voltage) of the clock signal CLKa is supplied to the drain electrode of the pull-up transistor Tup and the voltage of the first node Q is amplified by the capacitor between the gate electrode and the source electrode of the pull-up transistor Tup, so that the pull-up transistor Tup is stably turned on to output the gate-on voltage of the clock signal CLKa as an output voltage.

Subsequently, in the third period, the pull-up transistor Tup maintaining the turn-on state by floating the first node Q outputs the gate-off voltage (gate low voltage) of the clock signal CLKa as an output voltage.

Then, in the fourth period, the first node Q is discharged by the second transistor T2 turned on in response to the rear-end output NXT or the reset pulse Vrst, and the pull-up transistor Tup is turned off, so that the output voltage maintains the gate-off voltage.

Referring to FIG. 10, since the carry output unit OBc controlled by the first node Q1 is provided, the output units OBc and OBs are divided into a scan output unit OBs and a carry output unit OBc.

The scan output unit OBc includes a scan pull-up transistor Tup-S that outputs the clock pulse CLKa as the scan pulse SP in response to the control of the first node Q. The carry output unit OBc includes a carry pull-up transistor Tup-C that outputs the clock pulse CLKa as a carry signal CR in response to the control of the first node Q. The carry signal CR output from the carry output unit OBc is supplied as a front-end output PRE for the rear-end stage and is supplied as a rear-end output NXT for the front-end stage. Accordingly, the output node of the carry signal CR and the output node of the scan signal SP are separated to reduce the load of the carry signal CR, thereby reducing the delay of the carry signal CR that controls charging and discharging of the front-end and rear-end stages.

Referring to FIG. 10, a carry pull-down transistor Tdn-C in which the carry output unit OBc is controlled by the second node QB is additionally provided, a scan pull-down transistor Tdn-S in which the scan output unit OBs is controlled by the second node QB is additionally provided, and a second node control unit NC2 including an inverter INV connected between the first node Q and the second node QB is additionally provided.

The scan pull-down transistor Tdn-S of the scan output unit OBs supplies the first low potential voltage VSS0 as the first gate-off voltage of the scan signal SP in response to the control of the second node QB.

The carry pull-down transistor Tdn-C of the carry output unit OBc supplies the second low potential voltage VSS1 as the second gate-off voltage of the carry signal CR in response to the control of the second node QB. The carry signal CR output from the carry output unit OBc is supplied as a front-end output PRE for the rear-end stage and is supplied as a rear-end output NXT for the front-end stage. In the first node control unit NC1, the second transistor T2, which is a reset part, discharges the first node Q to a third low potential voltage VSS2, which is a reset voltage in response to the rear-end carry signal CRn.

The inverter INV of the second node control unit NC2 supplies a high potential voltage VH or a low potential voltage VL opposite to the voltage of the first node Q to the second node QB in response to the control of the first node Q.

The high potential voltages VDD and VH may be the same as or different from each other. The low potential voltages VSS0, VSS1, VSS2, and VL may be the same as or different from each other.

In addition, the first node control unit NC1 further includes a third transistor T3 of the noise cleaner controlled by the second node QB, the second node control unit NC2 includes an inverter INV composed of fourth to seventh transistors T4 to T7, and further includes an eighth transistor T8 controlled by the front-end output PRE. A third low potential voltage VSS2, which is a second reset voltage, is applied to the third transistor T3 of the noise cleaner, and a fourth low potential voltage VSS3, which is a first reset voltage, is applied to the second transistor T2 of the reset unit.

The third transistor T3 of the noise cleaner added to the first node control unit NC1 discharges the first node Q to the third low potential voltage VSS2 in response to the control of the second node QB. Accordingly, when the first node Q is a low logic, the third transistor T3 removes noise induced to the first node Q by the coupling of the clock CLKa supplied to the pull-up transistor Tup-C and Tup-S. The inverter INV of the second node control unit NC2 includes fourth to seventh transistors T4, T5, T6, and T7 to supply a high potential voltage VH or a low potential voltage VL to the second node QB so as to be opposite to the voltage of the first node Q. The eighth transistor T8 added to the second node control unit NC2 discharges the second node QB to a low potential voltage VL in response to the front-end output PRE.

A first capacitor C1 for amplifying the voltage of the gate electrode Q is formed between the gate electrode and the source electrode of the scan pull-up transistor Tup-S of the scan output unit OBs. A second capacitor C2 for amplifying the voltage of the gate electrode Q is formed between the gate electrode and the source electrode of the carry pull-up transistor Tup-C of the carry output unit OBc.

When the first node Q is in a charged state by the first node control unit NC1, the scan and carry pull-up transistors Tup-S and Tup-C output the clock signal CLKa as a scan signal SP and a carry signal CR, respectively.

When the second node QB is in a charged state by the second node control unit NC2, the scan and carry pull-down transistors Tdn-S and Tdn-C output the first and second low potential voltages VSS0 and VSS1 as a scan signal SP and a carry signal CR, respectively.

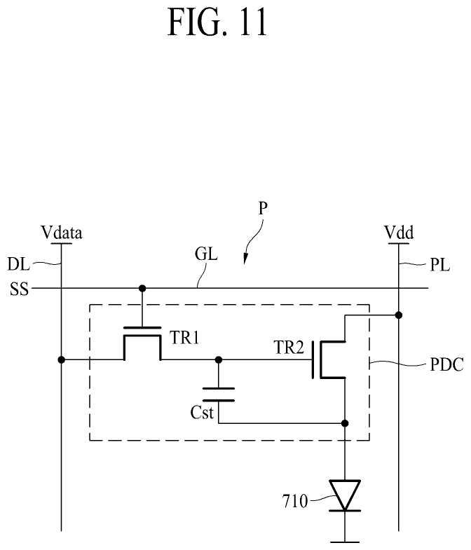

FIG. 11 is a circuit view illustrating any one pixel P of FIG. 8.

The circuit view of FIG. 11 is an equivalent circuit view for the pixel P of the display apparatus 1000 that includes an organic light emitting diode (OLED) as a display device 710.

Referring to FIG. 11, the pixel P includes a display device 710 and a pixel driving circuit PDC for driving the display device 710. In detail, the display apparatus 1000 according to one embodiment of the present disclosure may include a pixel driving circuit PDC on the base substrate 110.

The pixel driving circuit PDC of FIG. 11 includes a switching transistor and a driving transistor.

According to another embodiment of the present disclosure, the first thin film transistor TR1 of the thin film transistor substrates 100 and 200 described above may be used as the switching transistor. However, an embodiment of the present disclosure is not limited thereto, and the second thin film transistor TR2 of the thin film transistor substrates 100 and 200 described above may be used as the switching transistor of the pixel driving circuit PDC shown in FIG. 11.

According to another embodiment of the present disclosure, the second thin film transistor TR2 of the thin film transistor substrates 100 and 200 described above may be used as the driving transistor of the pixel driving circuit PDC shown in FIG. 11.

Hereinafter, for convenience of explanation, the display device 1000 will be described focusing on an embodiment in which the first thin film transistor TR1 of the thin film transistor substrates 100 and 200 described above is applied as a switching transistor and the second thin film transistor TR2 is applied as a driving transistor. The second thin film transistor TR2 is connected to the display device 710.

The first thin film transistor TR1, which is a switching transistor, is connected to the gate line GL and the data line DL and is turned on or off by the scan signal SS supplied through the gate line GL.

The data line DL provides the data voltage Vdata to the pixel driving circuit PDC, and the first thin film transistor TR1 controls application of the data voltage Vdata.

The driving power line PL provides a driving voltage Vdd to the display device 710, and the second thin film transistor TR2, which is a driving transistor, controls the driving voltage Vdd. The driving voltage Vdd is a pixel driving voltage for driving the organic light emitting diode OLED that is the display device 710.

When the second thin film transistor TR2 is turned on by the scan signal SS applied through the gate line GL from the gate driver 320, the data voltage Vdata supplied through the data line DL is supplied to the gate electrode of the second thin film transistor TR2 connected to the display device 710. The data voltage Vdata is charged in the storage capacitor Cst formed between the gate electrode and the source electrode of the second thin film transistor TR2.

According to the data voltage Vdata, the amount of current supplied to the organic light emitting diode OLED that is the display device 710 through the second thin film transistor TR2 is controlled, and accordingly, the gray level of light output from the display device 710 may be controlled.

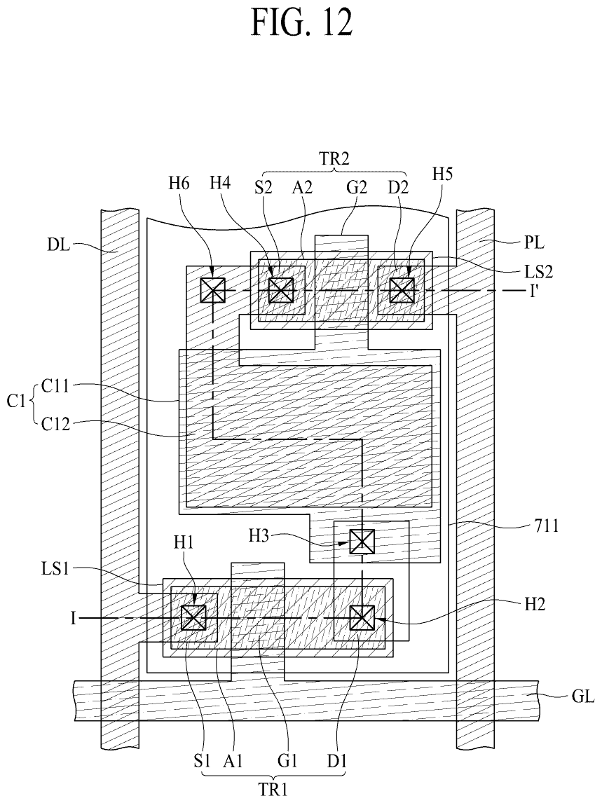

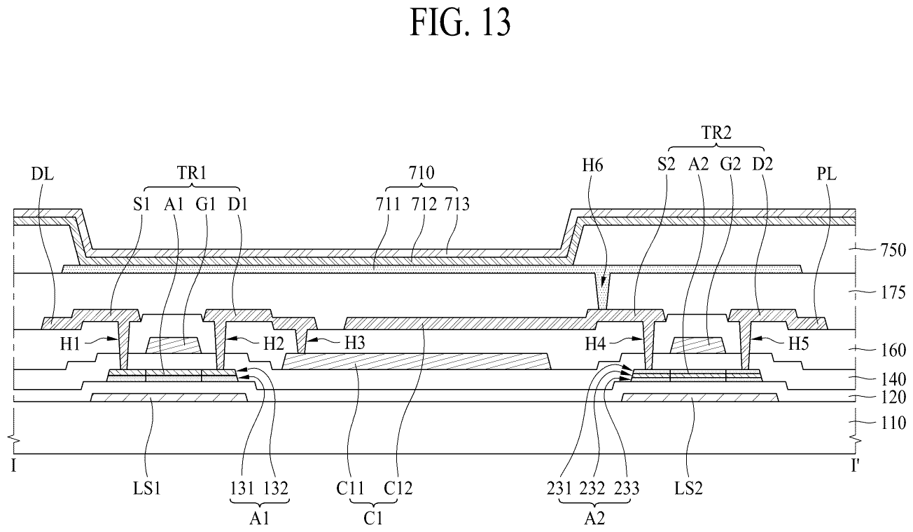

FIG. 12 is a plan view of the pixel of FIG. 11, and FIG. 13 is a cross-sectional view taken along line I-I′ of FIG. 12.

Referring to FIG. 13, light blocking layers LS1 and LS2 are disposed on the base substrate 110. In this case, the light blocking layers LS1 and LS2 correspond to the light blocking layers 111 and 211 shown in FIGS. 1 and 2.

The base substrate 110 may be made of glass or plastic. As the base substrate 110, plastic having flexible characteristics, for example, polyimide (PI) may be used.

The light blocking layers LS1 and LS2 shown in FIG. 13 are disposed to be spaced apart from each other.

The light blocking layers LS1 and LS2 may function as a light blocking layer. The light blocking layer protects the first active layer A1 of the first thin film transistor TR1 and the second active layer A2 of the second thin film transistor TR2 by blocking light incident from the outside.

Referring to FIG. 13, a buffer layer 120 may be disposed on the light blocking layers LS1 and LS2. The buffer layer 120 is disposed to cover an entire upper surface of the base substrate 110. The buffer layer 120 is formed of an insulating material and protects the active layers A1 and A2 from moisture, oxygen, and the like, which are introduced from the outside.

The active layer A1 of the first thin film transistor TR1 and the active layer A2 of the second thin film transistor TR2 may be disposed on the buffer layer 120.

The active layers A1 and A2 may include, for example, an oxide semiconductor material. The active layers A1 and A2 may be formed of an oxide semiconductor layer made of an oxide semiconductor material.

The active layers A1 and A2 of FIG. 13 may correspond to the first active layer 130 and the second active layer 230 illustrated in FIGS. 1 and 2. Although FIG. 13 exemplarily illustrates the first active layer 130 and the second active layer 230 of FIG. 1, an embodiment of the present disclosure is not limited thereto, and the first active layer 130 and the second active layer 230 of FIG. 2 may be illustrated.

The active layer A1 of the first thin film transistor TR1 of FIG. 13 includes a first oxide semiconductor layer 131 and a second oxide semiconductor layer 132, and the active layer A2 of the second thin film transistor TR2 includes a first oxide semiconductor layer 231, a second oxide semiconductor layer 232, and a third oxide semiconductor layer 233.

The first oxide semiconductor layer 131 of the active layer A1 of the first thin film transistor TR1 has an amorphous structure, and the second oxide semiconductor layer 132 has a crystalline structure. The first oxide semiconductor layer 231 and the third oxide semiconductor layer 233 of the active layer A2 of the second thin film transistor TR2 have an amorphous structure, and the second oxide semiconductor layer 232 has a crystalline structure.

A gate insulating layer 140 is disposed on the active layers A1 and A2. The gate insulating layer 140 may cover the entire upper surfaces of the active layers A1 and A2, or may cover only a part of the active layers A1 and A2.

The gate electrode G1 of the first thin film transistor TR1 and the gate electrode G2 of the second thin film transistor TR2 are disposed on the gate insulating layer 140.

The gate electrode G1 of the first thin film transistor TR1 overlaps at least a portion of the active layer A1. The gate electrode G2 of the second thin film transistor TR2 overlaps at least a portion of the active layer A2.

Referring to FIGS. 12 and 13, the first capacitor electrode C11 of the first capacitor C1 may be disposed on the same layer as the gate electrodes G1 and G2. The gate electrodes G1 and G2 and the first capacitor electrode C11 may be manufactured together by the same process using the same material.

An interlayer insulating layer 160 is disposed on the gate electrodes G1 and G2 and the first capacitor electrode C11.

The source electrodes S1 and S2 and the drain electrodes D1 and D2 are disposed on the interlayer insulating layer 160. According to an embodiment of the present disclosure, the source electrodes S1 and S2 and the drain electrodes D1 and D2 are only referred to for convenience of description, and the source electrodes S1 and S2 and the drain electrodes D1 and D2 may be switched.

Also, the data line DL and the driving power line PL are disposed on the interlayer insulating layer 160. The source electrode S1 of the first thin film transistor TR1 may be integrally formed with the data line DL. The drain electrode D2 of the second thin film transistor TR2 may be integrally formed with the driving power line PL.

According to an embodiment of the present disclosure, the source electrode S1 and the drain electrode D1 of the first thin film transistor TR1 are spaced apart from each other and are connected to the active layer A1 of the first thin film transistor TR1, respectively. The source electrode S2 and the drain electrode D2 of the second thin film transistor TR2 are spaced apart from each other and are connected to the active layer A2 of the second thin film transistor TR2, respectively.

The source electrode S1 of the first thin film transistor TR1 may be in contact with the source region of the active layer A1 through the first contact hole H1.

The drain electrode D1 of the first thin film transistor TR1 may be in contact with the drain region of the active layer A1 through the second contact hole H2, and may be connected to the first capacitor electrode C11 of the first capacitor C1 through the third contact hole H3.

The source electrode S2 of the second thin film transistor TR2 may extend onto the interlayer insulating layer 160 and a portion thereof may serve as the second capacitor electrode C12 of the first capacitor C1. The first capacitor electrode C11 and the second capacitor electrode C12 overlap to form a first capacitor C1.

In addition, the source electrode S2 of the second thin film transistor TR2 may contact the source region of the active layer A2 through the fourth contact hole H4.

The drain electrode D2 of the second thin film transistor TR2 may be in contact with the drain region of the active layer A2 through the fifth contact hole H5.

The first thin film transistor TR1 includes an active layer A1, a gate electrode G1, a source electrode S1, and a drain electrode D1, and serves as a switching transistor for controlling a data voltage Vdata applied to the pixel driver PDC.

The second thin film transistor TR2 includes an active layer A2, a gate electrode G2, a source electrode S2, and a drain electrode D2, and serves as a driving transistor for controlling a driving voltage Vdd applied to the display device 710.

A planarization layer 175 is disposed on the source electrodes S1 and S2, the drain electrodes D1 and D2, the data line DL and the driving power line PL. The planarization layer 175 planarizes the upper portions of the first thin film transistor TR1 and the second thin film transistor TR2 and protects the first thin film transistor TR1 and the second thin film transistor TR2.

A first electrode 711 of the display device 710 is disposed on the planarization layer 175. A first electrode 711 of the display device 710 may be connected to the source electrode S2 of the second thin film transistor TR2 through a sixth contact hole H6 formed in the planarization layer 175.

The bank layer 750 is disposed at an edge of the first electrode 711. The bank layer 750 defines a light emitting area of the display device 710.

The organic light emitting layer 712 is disposed on the first electrode 711, and the second electrode 713 is disposed on the organic light emitting layer 712. Accordingly, the display device 710 is completed. The display device 710 shown in FIG. 13 is an organic light emitting diode (OLED). Therefore, the display apparatus 1000 according to an embodiment of the present disclosure is an organic light emitting display apparatus.

According to the present disclosure, the following advantageous effects may be obtained.

The thin film transistor according to an embodiment of the present disclosure may simultaneously ensure excellent mobility and excellent reliability by applying an active layer to which a multi-layered structure is selectively applied.

The display apparatus according to an embodiment of the present disclosure including such a thin film transistor substrate may have excellent display performance and excellent reliability.

In addition to the above-mentioned effects, other features and advantages of the present disclosure will be described below or clearly understood by those of ordinary skill in the art to which the present disclosure belongs from such technology and description.

It will be apparent to those skilled in the art that the present disclosure described above is not limited by the above-described embodiments and the accompanying drawings and that various substitutions, modifications and variations can be made in the present disclosure without departing from the spirit or scope of the disclosures. Consequently, it is intended that all variations or modifications derived from the meaning, scope and equivalent concept of the claims fall within the scope of the present disclosure.

The various embodiments described above can be combined to provide further embodiments. Aspects of the embodiments can be modified, if necessary to employ concepts of the various embodiments to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A thin film transistor structure comprising:
a first thin film transistor and a second thin film transistor on a base substrate,
wherein the first thin film transistor includes:
a first active layer disposed on the base substrate; and
a first gate electrode spaced apart from the first active layer and overlapping at least part of the first active layer;
the second thin film transistor includes:
a second active layer disposed on the base substrate; and
a second gate electrode spaced apart from the second active layer and overlapping at least part of the second active layer;
the first active layer includes:
a first oxide semiconductor layer; and
a second oxide semiconductor layer disposed on the first oxide semiconductor layer;
the second active layer includes:
a first oxide semiconductor layer;
a second oxide semiconductor layer disposed on the first oxide semiconductor layer;
a third oxide semiconductor layer disposed on the second oxide semiconductor layer;
the first oxide semiconductor layer of the first active layer has an amorphous structure,
the second oxide semiconductor layer of the first active layer has a crystalline structure,
the first oxide semiconductor layer and the third oxide semiconductor layer of the second active layer have an amorphous structure, and
the second oxide semiconductor layer of the second active layer has a crystalline structure.

2. The thin film transistor structure of claim 1, wherein the first oxide semiconductor layer of the first active layer is made of a same material as the first oxide semiconductor layer of the second active layer.

3. The thin film transistor structure of claim 1, wherein the second oxide semiconductor layer of the first active layer is made of a same material as the second oxide semiconductor layer of the second active layer and has a same crystalline structure.

4. The thin film transistor substrate of claim 1, wherein the first oxide semiconductor layer of the first active layer, the first oxide semiconductor layer of the second active layer, and the third oxide semiconductor layer of the second active layer each includes at least one of an IZO (InZnO)-based, an IGZO (InGaZnO)-based, an IGZTO (InGaZnSnO)-based, a GZTO (GaZnSnO)-based, or a GZO (GaZnSnO)-based oxide semiconductor material, and
the second oxide semiconductor layer of the first active layer and the second oxide semiconductor layer of the second active layer each includes at least one of an IZO (InZnO)-based oxide semiconductor material, in which a concentration of In is 50% or more compared to a total concentration of In and Zn, an IGO (InGaO)-based, in which a concentration of In is 70% or more compared to a total concentration of In and Ga, an IGZO (InGaZnO)-based oxide semiconductor material, in which a concentration of In is 50% or more compared to a total concentration of In, Ga, and Zn, an ITO (InSnO)-based oxide semiconductor material, in which a concentration of In is 80% or more compared to a total concentration of In and Sn, an IGZTO (InGaZnSnO)-based oxide semiconductor material, in which a sum of concentration of In and Sn is 45% or more compared to a total concentration of In, Ga, Zn, and Sn, or an ITZO (InSnZnO)-based oxide semiconductor material, in which a sum of concentration of In and Sn is 45% or more compared to the total concentration of In, Sn, Zn based on atomic number.

5. The thin film transistor structure of claim 4, wherein each of the second oxide semiconductor layer of the first active layer and the second oxide semiconductor layer of the second active layer further includes a dopant in the oxide semiconductor material, and
the dopant includes at least one of beryllium (Be), boron (B), carbon (C), aluminum (Al), silicon (Si), iron (Fe), calcium (Ca), tin (Sn), titanium (Ti), tantalum (Ta), vanadium (V), yttrium (Y), zirconium (Zr), hafnium (Hf), lanthanum (La), or germanium (Ge).

6. The thin film transistor structure of claim 5, wherein the dopant included in the second oxide semiconductor layer of the first active layer has a concentration in a range from 0.1 to 10 atomic %, inclusive, based on a total number of atoms of the second oxide semiconductor layer of the first active layer, and
the dopant included in the second oxide semiconductor layer of the second active layer has a concentration in a range from 0.1 to 10 atomic %, inclusive, based on a total number of atoms of the second oxide semiconductor layer of the second active layer.

7. The thin film transistor structure of claim 1, wherein the first oxide semiconductor layer of the first active layer and the first oxide semiconductor layer of the second active layer each have a thickness in a range from 1 to 10 nm, inclusive,
the second oxide semiconductor layer of the first active layer and the second oxide semiconductor layer of the second active layer each have a thickness in a range from 10 to 50 nm, inclusive, and
the third oxide semiconductor layer of the second active layer has a thickness in a range from 1 to 20 nm, inclusive.

8. The thin film transistor structure of claim 1, wherein the second oxide semiconductor layer of the first active layer and the second oxide semiconductor layer of the second active layer have at least one of a (400) crystal plane, a (222) crystal plane, a (220) crystal plane, a (311) crystal plane, or a (0016) crystal plane.

9. The thin film transistor structure of claim 1, wherein the second oxide semiconductor layer of the first active layer and the second oxide semiconductor layer of the second active layer each have at least one of a Cubic crystal structure, a Bixbyite crystal structure, a Spinel crystal structure, or a hexagonal crystal structure.

10. The thin film transistor structure of claim 1, wherein the second oxide semiconductor layer of the first active layer and the second oxide semiconductor layer of the second active layer each include crystal grains having a particle diameter in a range from 3 to 500 nm, inclusive.

11. The thin film transistor structure of claim 1, wherein:
the first active layer includes:
a third oxide semiconductor layer disposed between the first oxide semiconductor layer and the second oxide semiconductor layer of the first active layer and having a crystalline structure; and
a fourth oxide semiconductor layer disposed on the second oxide semiconductor layer of the first active layer and having a crystalline structure; and
the second active layer includes:
a fourth oxide semiconductor layer disposed between the first oxide semiconductor layer and the second oxide semiconductor layer of the second active layer and having a crystalline structure; and
a fifth oxide semiconductor layer disposed between the second oxide semiconductor layer and the third oxide semiconductor layer of the second active layer and having a crystalline structure.

12. The thin film transistor structure of claim 11, wherein the third oxide semiconductor layer of the first active layer is made of a same material as the first oxide semiconductor layer of the first active layer,
the fourth oxide semiconductor layer of the second active layer is made of a same material as the first oxide semiconductor layer of the second active layer, and
the fifth oxide semiconductor layer of the second active layer is made of a same material as the third oxide semiconductor layer of the second active layer.

13. The thin film transistor structure of claim 11, wherein each of the third oxide semiconductor layer of the first active layer, the fourth oxide semiconductor layer of the first active layer, the fourth oxide semiconductor layer of the second active layer, and the fifth oxide semiconductor layer of the second active layer has a thickness of in a range from 0.1 to 3 nm, inclusive.

14. The thin film transistor structure of claim 11, wherein the third oxide semiconductor layer of the first active layer, the fourth oxide semiconductor layer of the first active layer, the fourth oxide semiconductor layer of the second active layer, and the fifth oxide semiconductor layer of the second active layer each have a (009) crystal plane and a CAAC crystal structure.

15. The thin film transistor structure of claim 11, wherein the third oxide semiconductor layer of the first active layer, the fourth oxide semiconductor layer of the first active layer, the fourth oxide semiconductor layer of the second active layer, and the fifth oxide semiconductor layer of the second active layer each include crystal grains having a particle diameter in a range from 1 to 10 nm, inclusive.

16. The thin film transistor structure of claim 1, wherein an s-factor of the second thin film transistor is greater than an s-factor of the first thin film transistor, and
a carrier mobility of the first thin film transistor is greater than a carrier mobility of the second thin film transistor.

17. A display apparatus comprising the thin film transistor structure of claim 1.

18. The display apparatus of claim 17, further including a gate driver and a pixel driving circuit on the base substrate,
the first thin film transistor is included in the gate driver or is a switching transistor of the pixel driving circuit, and
the second thin film transistor is a driving transistor of the pixel driving circuit.

19. A manufacturing method of a thin film transistor structure comprising:
preparing a base substrate placed in a first area and a second area;
forming a first active layer in the first area on the base substrate and forming a second active layer in the second area on the base substrate; and
forming a first gate electrode and a second gate electrode that at least partially overlap the first active layer and the second active layer, respectively.
the forming the first active layer and the second active layer includes:
stacking a first oxide semiconductor material layer, a second oxide semiconductor material layer, and a third oxide semiconductor material layer on the base substrate in order;
patterning the first oxide semiconductor material layer, the second oxide semiconductor material layer, and the third oxide semiconductor material layer to form a first active pattern and a second active pattern each including a first oxide semiconductor pattern layer, a second oxide semiconductor pattern layer, and a third oxide semiconductor pattern layer, respectively;
heat-treating the first active pattern and the second active pattern; and
wet etching the third oxide semiconductor pattern layer of the first active pattern using the photoresist material layer,
wherein the photoresist material layer overlaps the second active pattern disposed in the second area and does not overlap the first active pattern disposed in the first area.

20. The manufacturing method of the thin film transistor structure of claim 19, wherein the first oxide semiconductor material layer, the second oxide semiconductor material layer, and the third oxide semiconductor material layer are formed by sputtering deposition,
when the second oxide semiconductor material layer is formed, the sputtering deposition is performed at a temperature in a range from 100 to 300° C., inclusive, and
when the first oxide semiconductor material layer and the third oxide semiconductor material layer are formed, the sputtering deposition is performed at a temperature in a range from 15 to less than 100° C., inclusive.

21. The manufacturing method of the thin film transistor substrate of claim 19, wherein the heat-treating the first active pattern and the second active pattern is performed at a temperature in a range from 350 to 450° C.

22. A thin film transistor comprising:
an active layer; and
a gate electrode spaced apart from the active layer and overlapping at least part of the active layer;
wherein the active layer includes:
a first oxide semiconductor layer;
a second oxide semiconductor layer disposed on the first oxide semiconductor layer; and
a third oxide semiconductor layer disposed on the second oxide semiconductor layer; and
the first oxide semiconductor layer and the third oxide semiconductor have an amorphous structure, and the second oxide semiconductor layer has a crystalline structure.

23. The thin film transistor of claim 22, wherein the first oxide semiconductor layer and the third oxide semiconductor layer each include at least one of an IZO (InZnO)-based, an IGZO (InGaZnO)-based, an IGZTO (InGaZnSnO)-based, a GZTO (GaZnSnO)-based, or a GZO (GaZnO)-based oxide semiconductor material, and
the second oxide semiconductor layer includes at least one of an IZO (InZnO)-based oxide semiconductor material, in which a concentration of In is 50% or more compared to a total concentration of In and Zn, an IGO (InGaO)-based oxide semiconductor material, in which a concentration of In is 70% or more compared to a total concentration of In and Ga, an IGZO (InGaZnO)-based oxide semiconductor material, in which a concentration of In is 50% or more compared to a total concentration of In, Ga, and Zn, an ITO (InSnO)-based oxide semiconductor material, in which a concentration of In is 80% or more compared to a total concentration of In and Sn, an IGZTO (InGaZnSnO)-based oxide semiconductor material, in which a sum of concentration of In and Sn is 45% or more compared to a total concentration of In, Ga, Zn, and Sn, and an ITZO (InSnZnO)-based oxide semiconductor material, in which a sum of concentration of In and Sn is 45% or more compared to a total concentration of In, Sn, Zn based on atomic number.

24. The thin film transistor of claim 23, wherein the second oxide semiconductor layer further includes a dopant in the oxide semiconductor material, and
the dopant includes at least one of beryllium (Be), boron (B), carbon (C), aluminum (C), aluminum (Al), silicon (Si), iron (Si), calcium (Ca), tin (Sn), titanium (Ti), tantalum (Ta), vanadium (V), yttrium (Y), zirconium (Zr), hafnium (Hf), lanthanum (La), or germanium (Ge).

25. The thin film transistor of claim 24, wherein the dopant included in the second oxide semiconductor layer has a concentration in a range from 0.1 to 10 atomic %, inclusive, based on a total number of atoms in the second oxide semiconductor layer.

26. The thin film transistor of claim 22, wherein the first oxide semiconductor layer has a thickness in a range from 1 to 10 nm, inclusive,
the second oxide semiconductor layer has a thickness in a range from 10 to 50 nm, inclusive, and
the third oxide semiconductor layer has a thickness in a range from 1 to 20 nm, inclusive.

27. The thin film transistor of claim 22, wherein the second oxide semiconductor layer has at least one of a (400) crystal plane, a (222) crystal plane, a (220) crystal plane, a (311) crystal plane, or a (0016) crystal plane.

28. The thin film transistor of claim 22, wherein the second oxide semiconductor layer has at least one of a Cubic crystal structure, a Bixbyite crystal structure, a Spinel crystal structure, or a Hexagonal crystal structure.

29. The thin film transistor of claim 22, wherein the second oxide semiconductor layer includes a crystal grain having a particle diameter in a range from 3 nm to 500 nm, inclusive.

30. The thin film transistor of claim 22, wherein the active layer further includes:
a fourth oxide semiconductor layer disposed between the first oxide semiconductor layer and the second oxide semiconductor layer and having a crystalline structure; and
a fifth oxide semiconductor layer disposed between the second oxide semiconductor layer and the third oxide semiconductor layer and having a crystalline structure.

31. The thin film transistor of claim 30, wherein the fourth oxide semiconductor layer is made of the same material as the first oxide semiconductor layer, and
the fifth oxide semiconductor layer is made of a same material as the third oxide semiconductor layer.

32. The thin film transistor of claim 30, wherein each of the fourth oxide semiconductor layer and the fifth oxide semiconductor layer has a thickness in a range from 0.1 to 3 nm, inclusive.

33. The thin film transistor of claim 30, wherein the fourth oxide semiconductor layer and the fifth oxide semiconductor layer have a (009) crystal plane and a CAAC crystal structure.

34. The thin film transistor of claim 30, wherein the fourth oxide semiconductor layer and the fifth oxide semiconductor layer each include crystal grains having a particle diameter in a arrange from 1 to 10 nm, inclusive.

35. A structure comprising:
a first layer, and
a first semiconductor structure and a second semiconductor structure directly on the first layer, the first semiconductor structure including a first amorphous semiconductor layer and a first crystalline semiconductor layer on the first amorphous semiconductor layer, and the second semiconductor structure including a second amorphous semiconductor layer, a second crystalline semiconductor layer on the second amorphous semiconductor layer, and a third amorphous semiconductor layer on the second crystalline semiconductor layer; and
a second layer on the first crystalline semiconductor layer of the first semiconductor structure and on the third amorphous semiconductor layer of the second semiconductor structure.

36. The structure of claim 35, wherein the first layer and the second layer are insulating layers.

37. The structure of claim 35, wherein the second amorphous semiconductor layer, the second crystalline semiconductor layer, and the third amorphous semiconductor layer are oxide semiconductor layers.
